(19) United States
(12) Patent Application Publication
(10) Pub. No.: US 2026/0198122 A1
(43) Pub. Date: Jul. 9, 2026

(54) IMAGE SENSOR

(71) Applicant: Samsung Electronics Co., Ltd., Suwon-si (KR)

(72) Inventors: Hanseok Kim, Suwon-si (KR); Chanhyeon Seong, Suwon-si (KR); Eungkyu Lee, Suwon-si (KR); Jeong-Ho Lee, Suwon-si (KR)

(21) Appl. No.: 19/551,093

(22) Filed: Feb. 26, 2026

Related U.S. Application Data
(63) Continuation of application No. 18/169,954, filed on Feb. 16, 2023.

(30) Foreign Application Priority Data
Jun. 21, 2022 (KR) 10-2022-0075716

(51) Int. Cl. H10F 39/00; H10F 39/18

(52) U.S. Cl. CPC H10F 39/807; H10F 39/8063; H10F 39/811; H10F 39/182

(57) ABSTRACT

An image sensor includes a substrate having opposite first and second surfaces and including first to third unit pixels arranged in a first direction, and first and second pixel separation portions in the substrate and between, and separating from each other, separate adjacent unit pixels of the first to third unit pixels. The first pixel separation portion includes a first conductive pattern, and a first separation insulating pattern covering a sidewall of the first conductive pattern. The second pixel separation portion includes a second conductive pattern, and a second separation insulating pattern covering a sidewall of the second conductive pattern. The first conductive pattern has a first width in the first direction, and the second conductive pattern has a second width in the first direction, which is less than the first width.

### CROSS-REFERENCE TO RELATED APPLICATIONS

This application is a continuation of U.S. patent application Ser. No. 18/169,954, filed Feb. 16, 2023, which claims priority under 35 U.S.C. § 119 to Korean Patent Application No. 10-2022-0075716, filed on Jun. 21, 2022, in the Korean Intellectual Property Office, the entire contents of which are hereby incorporated by reference.

### BACKGROUND

The present inventive concepts relate to image sensors.

An image sensor is a semiconductor device for converting an optical image into electrical signals. Image sensors may be categorized as any one of charge coupled device (CCD) image sensors and complementary metal-oxide-semiconductor (CMOS) image sensors. CIS is short for the CMOS image sensor. The CIS may include a plurality of pixels two-dimensionally arranged. Each of the pixels may include a photodiode (PD). The photodiode may convert incident light into an electrical signal.

### SUMMARY

Some example embodiments of the inventive concepts may provide an image sensor capable of realizing clear (e.g., improved) image quality.

In some example embodiments, an image sensor may include a substrate having a first surface and a second surface opposite to the first surface, the substrate including first to third unit pixels arranged in a first direction, the first direction extending parallel to the second surface of the substrate, a first pixel separation portion in the substrate and between the first unit pixel and the second unit pixel to separate the first and second unit pixels from each other, and a second pixel separation portion in the substrate and between the second unit pixel and the third unit pixel to separate the second and third unit pixels from each other. The first pixel separation portion may include a first conductive pattern, and a first separation insulating pattern covering a sidewall of the first conductive pattern. The second pixel separation portion may include a second conductive pattern, and a second separation insulating pattern covering a sidewall of the second conductive pattern. The first conductive pattern may have a first width in the first direction, and the second conductive pattern may have a second width in the first direction, which is less than the first width.

In some example embodiments, an image sensor may include a substrate having a first surface and a second surface opposite to the first surface, the substrate including first to third unit pixels arranged in a first direction, the first direction extending parallel to the second surface of the substrate, a first pixel separation portion disposed in the substrate and disposed between the first unit pixel and the second unit pixel to separate the first and second unit pixels from each other, and a second pixel separation portion in the substrate and between the second unit pixel and the third unit pixel to separate the second and third unit pixels from each other. The first pixel separation portion may include a first conductive pattern, and a first separation insulating pattern covering a sidewall of the first conductive pattern. The second pixel separation portion may include a second separation insulating pattern and may exclude the first conductive pattern. The first pixel separation portion may have a first width in the first direction, and the second pixel separation portion may have a second width in the first direction, which is less than the first width.

In some example embodiments, an image sensor may include a substrate having a first surface and a second surface opposite to the first surface, the substrate including first to third unit pixels arranged in a first direction, the first direction extending parallel to the second surface of the substrate, a transfer gate on the first surface of the substrate in each of the first to third unit pixels, a first interlayer insulating layer covering the first surface of the substrate, a first pixel separation portion disposed in the substrate and disposed between the first unit pixel and the second unit pixel to separate the first and second unit pixels from each other, a second pixel separation portion disposed in the substrate and disposed between the second unit pixel and the third unit pixel to separate the second and third unit pixels from each other, a first light blocking pattern disposed on the second surface of the substrate and overlapping the first pixel separation portion, and a second light blocking pattern disposed on the second surface of the substrate and overlapping the second pixel separation portion. The first pixel separation portion may include a first conductive pattern, a first separation insulating pattern covering a sidewall of the first conductive pattern, and a first filling insulation pattern between the first conductive pattern and the first interlayer insulating layer. The second pixel separation portion may include a second conductive pattern, a second separation insulating pattern covering a sidewall of the second conductive pattern, and a second filling insulation pattern between the second conductive pattern and the first interlayer insulating layer. The first pixel separation portion may have a first width in the first direction, and the second pixel separation portion may have a second width in the first direction, which is less than the first width. The first light blocking pattern may have a third width in the first direction, and the second light blocking pattern may have a fourth width in the first direction, which is less than the third width.

### BRIEF DESCRIPTION OF THE DRAWINGS

FIG. 1 is a block diagram illustrating an image sensor according to some example embodiments of the inventive concepts.

FIG. 2 is a circuit diagram illustrating an active pixel sensor array of an image sensor according to some example embodiments of the inventive concepts.

FIG. 3 is a plan view illustrating an image sensor including a low-refractive pattern according to some example embodiments of the inventive concepts.

FIG. 4 is a plan view illustrating an image sensor including a pixel separation portion according to some example embodiments of the inventive concepts.

FIG. 5A is a cross-sectional view taken along a line A-A′ of FIG. 3 and/or FIG. 4 according to some example embodiments of the inventive concepts.

FIG. 5B is a cross-sectional view taken along the line A-A′ of FIG. 3 according to some example embodiments of the inventive concepts.

FIG. 6 is a plan view illustrating an image sensor including a pixel separation portion according to some example embodiments of the inventive concepts.

FIG. 7A is a cross-sectional view taken along a line A-A′ of FIG. 6 according to some example embodiments of the inventive concepts.

FIG. 7B is a cross-sectional view taken along a line B-B′ of FIG. 6 according to some example embodiments of the inventive concepts.

FIGS. 8A and 8B are cross-sectional views illustrating a method of manufacturing an image sensor having the cross section of FIG. 5A.

FIG. 9 is a plan view illustrating an image sensor according to some example embodiments of the inventive concepts.

FIG. 10 is a plan view illustrating an image sensor according to some example embodiments of the inventive concepts.

FIG. 11 is a cross-sectional view taken along a line A-A′ of FIG. 10.

FIG. 12A is a plan view illustrating an image sensor having a low-refractive pattern according to some example embodiments of the inventive concepts.

FIG. 12B is a plan view illustrating an image sensor having a pixel separation portion according to some example embodiments of the inventive concepts.

FIGS. 13A and 13B are plan views illustrating image sensors having low-refractive patterns according to some example embodiments of the inventive concepts.

FIG. 14 is a cross-sectional view illustrating an image sensor according to some example embodiments of the inventive concepts.

FIG. 15 is a cross-sectional view illustrating an image sensor according to some example embodiments of the inventive concepts.

FIG. 16 is a cross-sectional view illustrating an image sensor according to some example embodiments of the inventive concepts.

FIG. 17 is a cross-sectional view illustrating an image sensor according to some example embodiments of the inventive concepts.

FIG. 18 is a cross-sectional view illustrating an image sensor according to some example embodiments of the inventive concepts.

### DETAILED DESCRIPTION

Hereinafter, to describe the inventive concepts in more detail, some example embodiments of the inventive concepts will now be described more fully with reference to the accompanying drawings. In this specification, terms indicating an order such as first, and second, are used to distinguish components having the same/similar functions as/to each other, and the first and second may be changed depending on an order in which they are mentioned.

It will be understood that when an element is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular” with regard to other elements and/or properties thereof will be understood to be “perpendicular” with regard to the other elements and/or properties thereof within manufacturing tolerances and/or material tolerances and/or have a deviation in magnitude and/or angle from “perpendicular,” or the like with regard to the other elements and/or properties thereof that is equal to or less than 10% (e.g., a. tolerance of ±10%).

Elements and/or properties thereof (e.g., structures, surfaces, directions, or the like) that are “substantially parallel” with regard to other elements and/or properties thereof will be understood to be “parallel” with regard to the other elements and/or properties thereof within manufacturing tolerances and/or material tolerances and/or have a deviation in magnitude and/or angle from “parallel,” or the like with regard to the other elements and/or properties thereof that is equal to or less than 10% (e.g., a. tolerance of ±10%).

Elements and/or properties thereof (e.g., structures, surfaces, directions, or the like) that are “substantially coplanar” with regard to other elements and/or properties thereof will be understood to be “coplanar” with regard to the other elements and/or properties thereof within manufacturing tolerances and/or material tolerances and/or have a deviation in magnitude and/or angle from “coplanar,” or the like with regard to the other elements and/or properties thereof that is equal to or less than 10% (e.g., a. tolerance of ±10%)).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value include a tolerance of ±10% around the stated numerical value. When ranges are specified, the range includes all values therebetween such as increments of 0.1%.

While the term “same,” “equal” or “identical” may be used in description of some example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

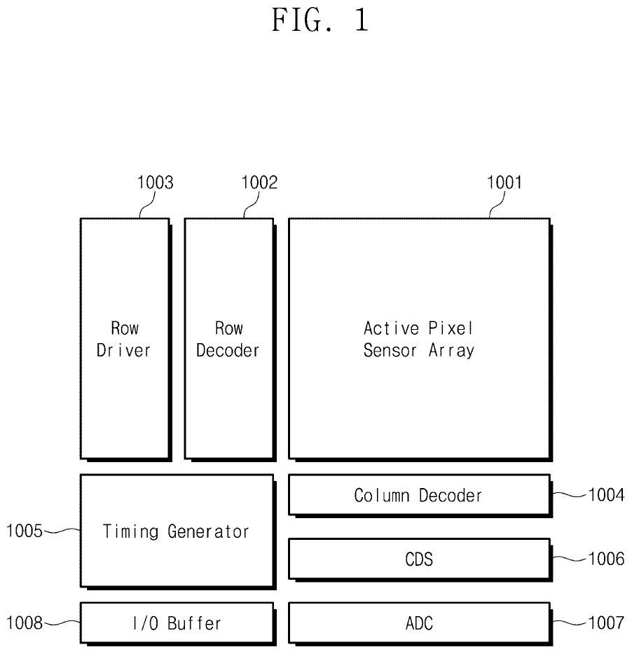

FIG. 1 is a block diagram illustrating an image sensor according to some example embodiments of the inventive concepts.

Referring to FIG. 1, an image sensor may include an active pixel sensor array 1001, a row decoder 1002, a row driver 1003, a column decoder 1004, a timing generator 1005, a correlated double sampler (CDS) 1006, an analog-to-digital converter (ADC) 1007, and an input/output (I/O) buffer 1008.

The active pixel sensor array 1001 may include a plurality of unit pixels two-dimensionally arranged and may convert optical signals into electrical signals. The active pixel sensor array 1001 may be driven by a plurality of driving signals (e.g., a pixel selection signal, a reset signal, and a charge transfer signal) provided from the row driver 1003. In addition, the converted electrical signals may be provided to the correlated double sampler 1006.

The row driver 1003 may provide a plurality of driving signals for driving a plurality of the unit pixels to the active pixel sensor array 1001 in response to signals decoded in the row decoder 1002. When the unit pixels are arranged in a matrix form, the driving signals may be provided in the unit of row of the matrix.

The timing generator 1005 may provide timing signals and control signals to the row decoder 1002 and the column decoder 1004.

The correlated double sampler 1006 may receive electrical signals generated from the active pixel sensor array 1001 and may hold and sample the received electrical signals. The correlated double sampler 1006 may doubly sample a specific noise level and a signal level of the electrical signal to output a difference level corresponding to a difference between the noise level and the signal level.

The analog-to-digital converter 1007 may convert an analog signal, which corresponds to the difference level outputted from the correlated double sampler 1006, into a digital signal and may output the digital signal.

The I/O buffer 1008 may latch the digital signals, and the latched signals may be sequentially outputted to an image signal processing unit (not shown) in response to signals decoded in the column decoder 1004.

As described herein, any devices, electronic devices, modules, units, circuits, and/or portions thereof according to any of the example embodiments, and/or any portions thereof (including, without limitation, the image sensor shown in FIG. 1 and/or an electronic device including such an image sensor, the active pixel sensor array 1001, the row decoder 1002, the row driver 1003, the column decoder 1004, the timing generator 1005, the CDS 1006, the ADC 1007, the I/O buffer 1008, or the like) may include, may be included in, and/or may be implemented by one or more instances of processing circuitry such as hardware including logic circuits; a hardware/software combination such as a processor executing software; or a combination thereof. For example, the processing circuity more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., a CPU) configured to execute the program of instructions to implement the functionality and/or methods performed by some or all of any devices, electronic devices, modules, units, circuits, and/or portions thereof, according to any of the example embodiments, including any of the methods according to any of the example embodiments.

Any of the memories described herein may be a non-transitory computer readable medium and may store a program of instructions. Any of the memories described herein may be a nonvolatile memory, such as a flash memory, a phase-change random access memory (PRAM), a magneto-resistive RAM (MRAM), a resistive RAM (ReRAM), or a ferro-electric RAM (FRAM), or a volatile memory, such as a static RAM (SRAM), a dynamic RAM (DRAM), or a synchronous DRAM (SDRAM).

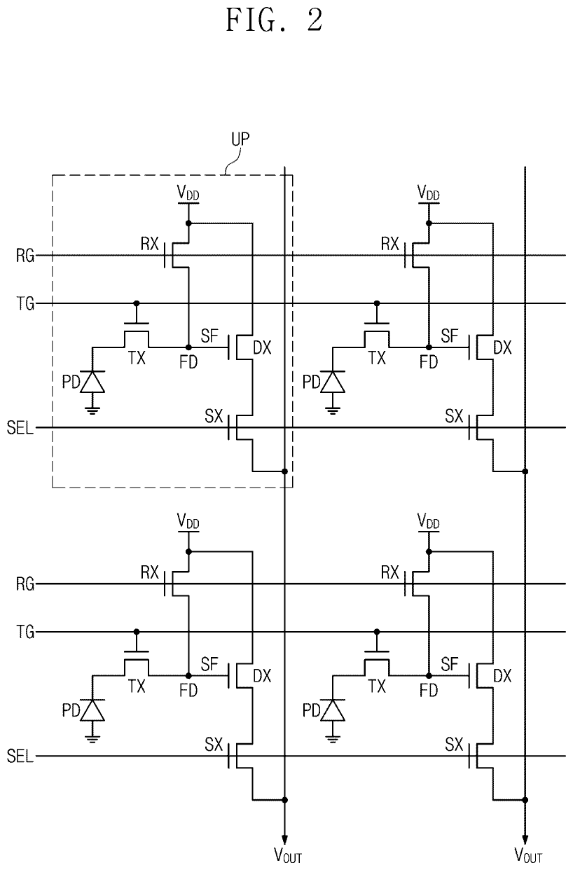

FIG. 2 is a circuit diagram illustrating an active pixel sensor array of an image sensor according to some example embodiments of the inventive concepts.

Referring to FIGS. 1 and 2, the active pixel sensor array 1001 may include a plurality of unit pixels UP, and the unit pixels UP may be arranged in a matrix form. Each of the unit pixels UP may include a transfer transistor TX. Each of the unit pixels UP may further include logic transistors RX, SX and DX. The logic transistors RX, SX and DX may include a reset transistor RX, a selection transistor SX, and a source follower transistor DX. The transfer transistor TX may include a transfer gate TG. Each of the unit pixels UP may further include a photoelectric conversion portion PD and a floating diffusion region FD. The logic transistors RX, SX and DX may be shared by a plurality of the unit pixels UP.

The photoelectric conversion portion PD may generate and accumulate photocharges in proportion to the amount of light incident from the outside. The photoelectric conversion portion PD may include a photodiode, a photo transistor, a photo gate, a pinned photodiode, or a combination thereof. The transfer transistor TX may transfer charges generated in the photoelectric conversion portion PD to the floating diffusion region FD. The floating diffusion region FD may receive the charges generated in the photoelectric conversion portion PD and may cumulatively store the received charges. The source follower transistor DX may be controlled according to the amount of the photocharges accumulated in the floating diffusion region FD.

The reset transistor RX may periodically reset the charges accumulated in the floating diffusion region FD. A drain electrode of the reset transistor RX may be connected to the floating diffusion region FD, and a source electrode of the reset transistor RX may be connected to a power voltage V_{DD}. When the reset transistor RX is turned-on, the power voltage V_{DD} connected to the source electrode of the reset transistor RX may be applied to the floating diffusion region FD. Thus, when the reset transistor RX is turned-on, the charges accumulated in the floating diffusion region FD may be discharged to reset the floating diffusion region FD.

The source follower transistor DX including a source follower gate electrode SF may function as a source follower buffer amplifier. The source follower transistor DX may amplify a potential change in the floating diffusion region FD and may output the amplified potential change to an output line V_{OUT}.

The selection transistor SX including a selection gate electrode SEL may select the unit pixels UP to be sensed in the unit of row. When the selection transistor SX is turned-on, the power voltage V_{DD} may be applied to a drain electrode of the source follower transistor DX.

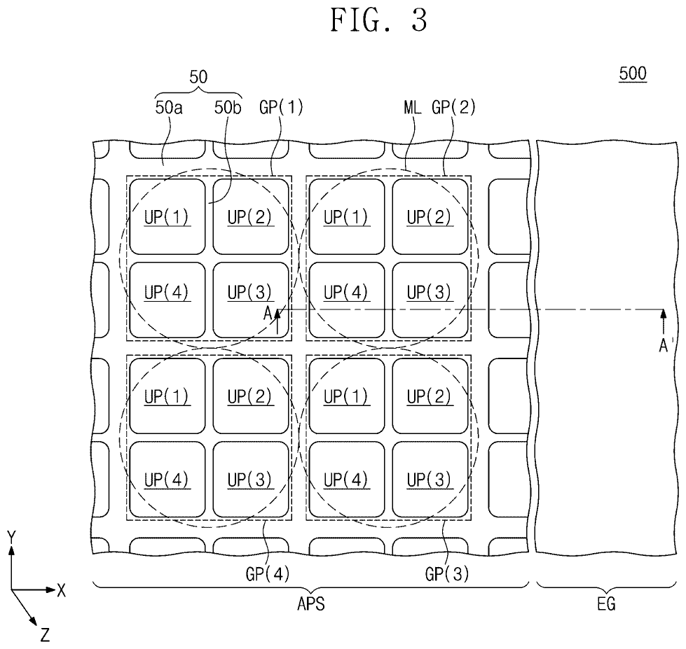

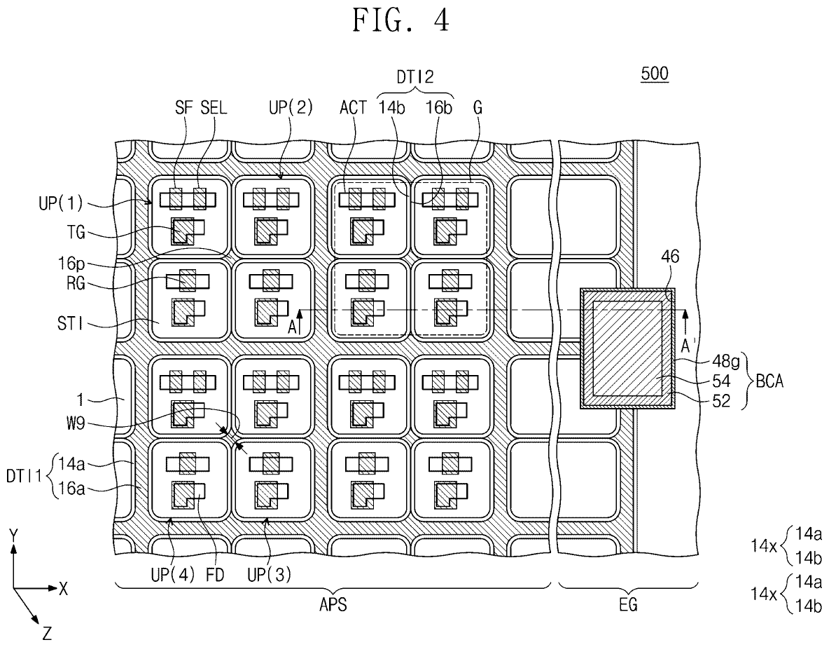

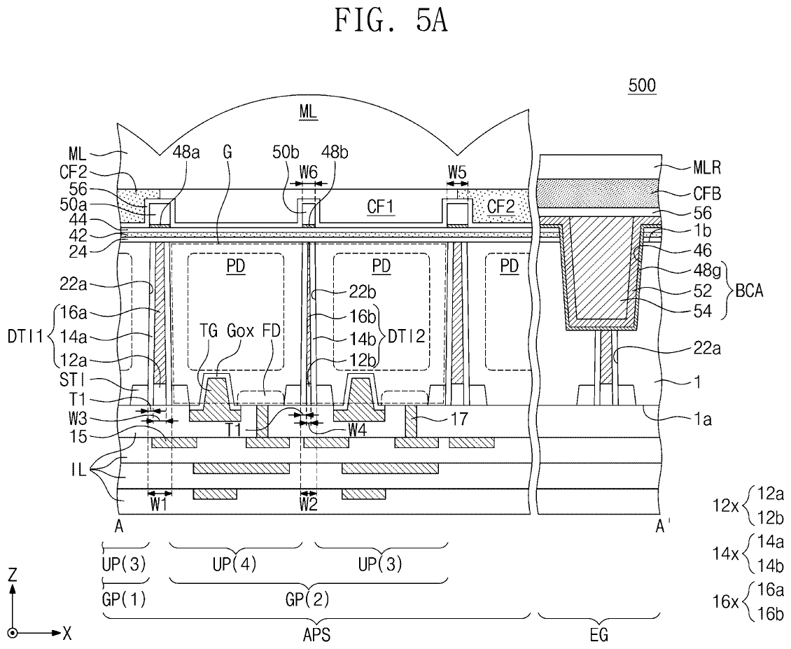

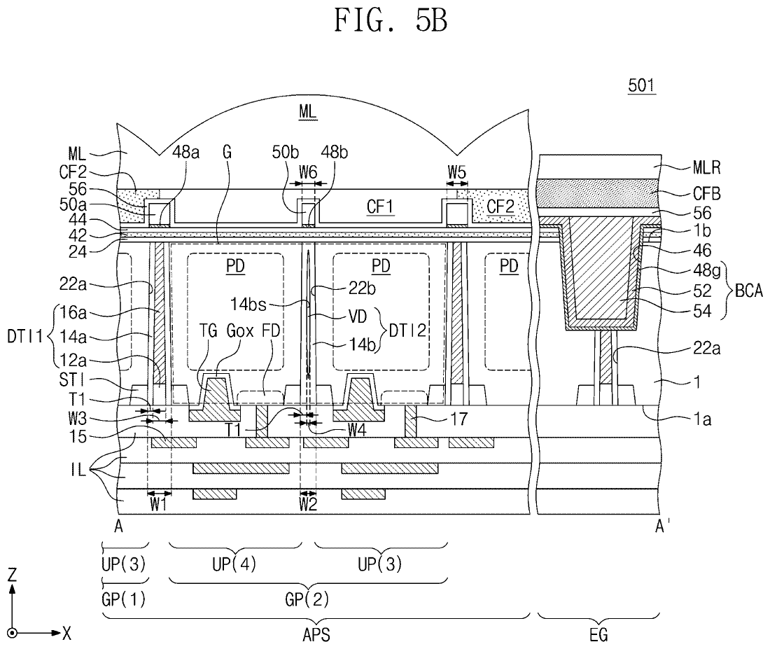

FIG. 3 is a plan view illustrating an image sensor including a low-refractive pattern according to some example embodiments of the inventive concepts. FIG. 4 is a plan view illustrating an image sensor including a pixel separation portion according to some example embodiments of the inventive concepts. FIG. 5A is a cross-sectional view taken along a line A-A′ of FIG. 3 and/or FIG. 4 according to some example embodiments of the inventive concepts.

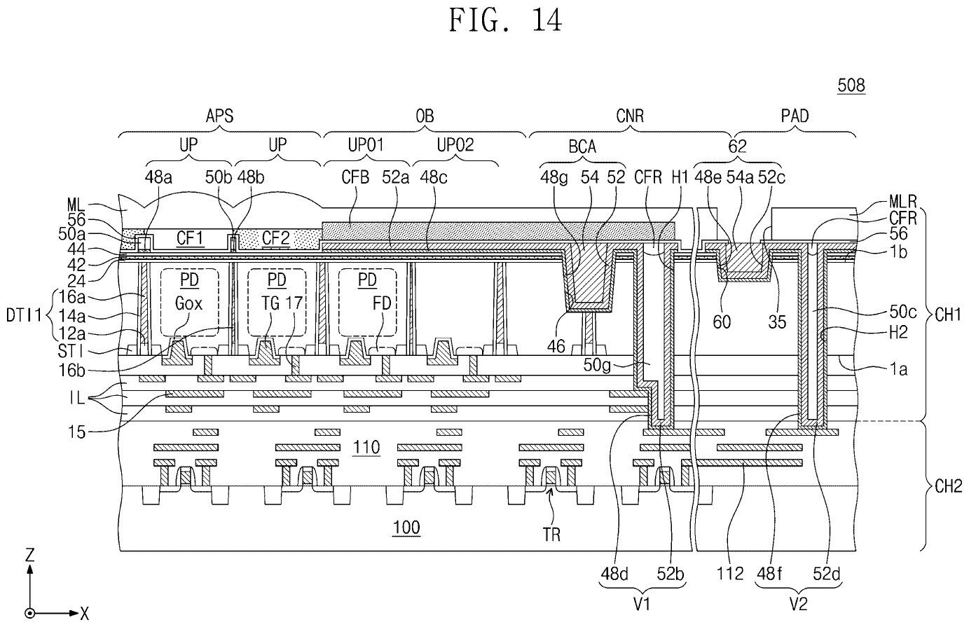

Referring to FIGS. 3, 4 and 5A, an image sensor 500 according to some example embodiments of the inventive concepts may include a first substrate 1. For example, the first substrate 1 may be a single-crystalline silicon wafer, a silicon epitaxial layer, or a silicon-on-insulator (SOI) substrate. For example, the first substrate 1 may be doped with dopants having a first conductivity type. For example, the first conductivity type may be a P-type. The first substrate 1 may include a first surface 1a and a second surface 1b which are opposite to each other. The first substrate 1 may include a pixel array region APS and an edge region EG. The pixel array region APS may include a plurality of unit pixels UP. The edge region EG may correspond to a portion of a connection region CNR of FIG. 14.

Pixel separation portions DTI1 and DTI2 may be disposed in the first substrate 1 (e.g., at least partially or entirely within an interior of the first substrate 1 between the first and second surfaces 1a and 1b of the first substrate 1) to separate/define (e.g., isolate) the unit pixels UP from each other (e.g., isolate separate unit pixels UP from direct contact with each other in the first direction X and/or the second direction Y) in the pixel array region APS. As shown in at least FIG. 4, the pixel separation portions DTI1 and DTI2 may extend into the edge region EG. Four unit pixels UP, which are adjacent to each other and constitute two rows and two columns, of the unit pixels UP may constitute a pixel group GP. The unit pixels UP may include first to fourth unit pixels UP(1) to UP(4) adjacent to each other in a clockwise direction. The first to fourth unit pixels UP(1) to UP(4) adjacent to each other may constitute each of first to fourth pixel groups GP(1) to GP(4). The first to fourth pixel groups GP(1) to GP(4) may be adjacent to each other in the clockwise direction. The first and second unit pixels UP(1) and UP(2) may be arranged in a first direction X. The fourth and third unit pixels UP(4) and UP(3) may be arranged in the first direction X. The fourth and first unit pixels UP(4) and UP(1) may be arranged in a second direction Y intersecting the first direction X. The third and second unit pixels UP(3) and UP(2) may be arranged in the second direction Y.

As shown, the first direction X may be understood to extend parallel to (e.g., extend in parallel with) at least one of the first surface 1a or the second surface 1b of the first substrate 1 and in some example embodiments may be referred to as extending parallel to the first substrate 1 based on extending parallel to at least one of the first surface 1a or the second surface 1b of the first substrate 1. As further shown, the second direction Y may be understood to extend parallel to (e.g., extend in parallel with) at least one of the first surface 1a or the second surface 1b of the first substrate 1 (in addition to intersecting the first direction X, which may include extending perpendicular to the first direction X), and in some example embodiments may be referred to as extending parallel to the first substrate 1 based on extending parallel to at least one of the first surface 1a or the second surface 1b of the first substrate 1.

The pixel separation portions DTI1 and DTI2 may include first and second pixel separation portions DTI1 and DTI2. The first pixel separation portions DTI1 may surround each of the first to fourth pixel groups GP(1) to GP(4) when viewed in a plan view. For example, the first pixel separation portions DTI1 may partially or completely surround each of the first to fourth pixel groups GP(1) to GP(4) in a horizontal plane that extends in the first and second directions X and Y (e.g., in an XY plane). The first pixel separation portions DTI1 may have a mesh shape when viewed in a plan view. For example, as illustrated in FIGS. 4 and 5A, where the third unit pixel UP(3) of the first pixel group GP(1), the fourth unit pixel UP(4) of the second pixel group GP(2), and the third unit pixel UP(3) of the second pixel group GP(2) may be referred to as first to third unit pixels arrange in the first direction X in the first substrate 1, the first pixel separation portion DTI1 may be disposed between the third unit pixel UP(3) of the first pixel group GP(1) and the fourth unit pixel UP(4) of the second pixel group GP(2) in at least the first direction X and thus may separate (e.g., isolate) the third unit pixel UP(3) of the first pixel group GP(1) and the fourth unit pixel UP(4) of the second pixel group GP(2) (e.g., the first and second unit pixels) from each other in at least the first direction X. The second pixel separation portion DTI2 may be disposed between the fourth unit pixel UP(4) and the third unit pixel UP(3) of the second pixel group GP(2) in at least the first direction X and thus may separate (e.g., isolate) the fourth unit pixel UP(4) and the third unit pixel UP(3) of the second pixel group GP(2) (e.g., the second and third unit pixels) from each other in at least the first direction X.

The second pixel separation portions DTI2 may protrude from sidewalls of the first pixel separation portions DTI1 and may be disposed between the first to fourth unit pixels UP(1) to UP(4) of a given pixel group GP. The second pixel separation portions DTI2 may have a cross shape when viewed in a plan view.

A photoelectric conversion portion PD may be disposed in the first substrate 1 of each of the unit pixels UP. The photoelectric conversion portions PD may be doped with dopants having a second conductivity type opposite to the first conductivity type. For example, the second conductivity type may be an N-type. The N-type dopants included in the photoelectric conversion portion PD may form a PN junction with the P-type dopants included in the first substrate 1 around the photoelectric conversion portion PD, and thus a photodiode may be provided.

Device separation portions STI adjacent to the first surface 1a may be disposed in the first substrate 1. The first and second pixel separation portions DTI1 and DTI2 may penetrate the device separation portions STI. The device separation portion STI may define active regions ACT adjacent to the first surface 1a in each of the unit pixels UP. The active regions ACT may be provided for the transistors TX, RX, DX and SX of FIG. 2.

A transfer gate TG may be disposed on the first surface 1a of the first substrate 1 of each of the unit pixels UP. A portion of the transfer gate TG may extend into the first substrate 1. The transfer gate TG may be a vertical type gate. In some example embodiments, the transfer gate TG may not extend into the first substrate 1 but may be a planar type gate having a flat shape. A gate insulating layer Gox may be disposed between the transfer gate TG and the first substrate 1. A floating diffusion region FD may be disposed in the first substrate 1 at a side of the transfer gate TG. For example, the floating diffusion region FD may be doped with dopants having the second conductivity type.

The image sensor 500 may be a backside illuminated image sensor. Light may be incident into the first substrate 1 through the second surface 1b of the first substrate 1. Electron-hole pairs (EHPs) may be generated in a depletion region of the PN junction by the incident light. The generated electrons may move into the photoelectric conversion portion PD. When a voltage is applied to the transfer gate TG, the electrons may be moved into the floating diffusion region FD.

In one unit pixel UP(3) or UP(4), a reset gate RG may be disposed on the first surface 1a and may be adjacent to the transfer gate TG. In another unit pixel UP(1) or UP(2), a source follower gate SF and a selection gate SEL may be disposed on the first surface 1a and may be adjacent to the transfer gate TG. The gates TG, RG, SF and SEL may correspond to gates of the transistors TX, RX, DX and SX of FIG. 2, respectively. The gates TG, RG, SF and SEL may overlap (e.g., in the third direction Z) with the active regions ACT. In some example embodiments, the reset transistor RX, the selection transistor SX and the source follower transistor DX may be shared by two unit pixels UP adjacent to each other (e.g., two adjacent unit pixels UP in a same given pixel group GP and/or two adjacent unit pixels UP of different pixel groups GP).

The first surface 1a may be covered with first interlayer insulating layers IL. Each of the first interlayer insulating layers IL may include at least one of a silicon oxide layer, a silicon nitride layer, a silicon oxynitride layer, or a porous low-k dielectric layer. First interconnection lines 15 may be disposed between or in the first interlayer insulating layers IL. The floating diffusion region FD may be connected to a corresponding one of the first interconnection lines 15 through a first contact plug 17. The first contact plug 17 may penetrate a first interlayer insulating layer IL, closest to the first surface 1a, of the first interlayer insulating layers IL in the pixel array region APS.

The first pixel separation portion DTI1 may be located in a first trench 22a formed from the first surface 1a toward the second surface 1b (e.g., at least partially defined by one or more inner surfaces of the first substrate 1 which extend from the first surface 1a toward the second surface 1b). The second pixel separation portion DTI2 may be located in a second trench 22b formed from the first surface 1a toward the second surface 1b (e.g., at least partially defined by one or more inner surface of the first substrate which extend from the first surface 1a toward the second surface 1b). In the cross-sectional view of FIG. 5A, each of the first pixel separation portion DTI1 and the first trench 22a may have a first width W1 in the first direction X. Each of the second pixel separation portion DTI2 and the second trench 22b may have a second width W2 in the first direction X. The second width W2 may be less (e.g., smaller) than the first width W1. The second pixel separation portion DTI2 may have the second width W2 which is relatively narrow, and thus a size of the image sensor may be reduced. As a result, a highly integrated image sensor may be provided. For example, compactness of the image sensor 500 including the first and second pixel separation portions DTI1 and DTI2 may be improved, thereby improving space efficiency of the image sensor 500, based on the first conductive pattern DTI1 having a first width W1 in the first direction X, and the second conductive pattern DTI2 having a second width W2 in the first direction X, where the second width W2 is less (e.g., smaller) than the first width W1.

The first pixel separation portion DTI1 may include a first filling insulation pattern 12a, a first separation insulating pattern 14a, and a first conductive pattern 16a. The first filling insulation pattern 12a may be disposed between (e.g., between in the third direction Z) the first conductive pattern 16a and the first interlayer insulating layer IL. The first separation insulating pattern 14a may be disposed between (e.g., between in the first direction X and/or the second direction Y) the first conductive pattern 16a and the first substrate 1 and between (e.g., between in the first direction X and/or the second direction Y) the first filling insulation pattern 12a and the first substrate 1.

The second pixel separation portion DTI2 may include a second filling insulation pattern 12b, a second separation insulating pattern 14b, and a second conductive pattern 16b. The second filling insulation pattern 12b may be disposed between (e.g., between in the third direction Z) the second conductive pattern 16b and the first interlayer insulating layer IL. The second separation insulating pattern 14b may be disposed between (e.g., between in the first direction X and/or the second direction Y) the second conductive pattern 16b and the first substrate 1 and between (e.g., between in the first direction X and/or the second direction Y) the second filling insulation pattern 12b and the first substrate 1.

In some example embodiments, the first and second pixel separation portions DTI1 and DTI2 may include separate portions of one or more unitary pieces of material, where the second pixel separation portions DTI2 include portions of the one or more unitary pieces of material that are located between at least two unit pixels UP of a given (e.g., same) pixel group GP in the first and/or second directions X and/or Y and where the first pixel separation portions DTI1 include portions of the one or more unitary pieces of material that are located between at least two unit pixels UP of separate (e.g., different) pixel groups GP in the first and/or second directions X and/or Y, where the one or more unitary pieces of material each extend continuously between the first and second pixel separation portions DTI1 and DTI2. For example, the first and second filling insulation patterns 12a and 12b may be separate portions of a filling insulation pattern 12x that is a single unitary piece of material extending continuously at least partially between separate unit pixels UP of pixel groups GP and between separate unit pixels UP of a same pixel group GP, where the first filling insulation pattern 12a is a first portion of the single unitary piece of material of the filling insulation pattern 12x that is located between at least two unit pixels UP of a given (e.g., same) pixel group GP in the first and/or second directions X and/or Y and where the second filling insulation pattern 12b is a second portion of the single unitary piece of material of the filling insulation pattern 12x that is located between at least two unit pixels UP of separate (e.g., different) pixel groups GP in the first and/or second directions X and/or Y). In another example, the first and second separation insulating patterns 14a and 14b may be separate portions of a separation insulating pattern 14x that is a single unitary piece of material extending continuously at least partially between separate unit pixels UP of pixel groups GP and between separate unit pixels UP of a same pixel group GP, where the first separation insulating pattern 14a is a first portion of the single unitary piece of material of the separation insulating pattern 14x that is located between at least two unit pixels UP of a given (e.g., same) pixel group GP in the first and/or second directions X and/or Y and where the second separation insulating pattern 14b is a second portion of the single unitary piece of material of the separation insulating pattern 14x that is located between at least two unit pixels UP of separate (e.g., different) pixel groups GP in the first and/or second directions X and/or Y). In another example, the first and second conductive patterns 16a and 16b may be separate portions of a conductive pattern 16x that is a single unitary piece of material extending continuously at least partially between separate unit pixels UP of pixel groups GP and between separate unit pixels UP of a same pixel group GP, where the first conductive pattern 16a is a first portion of the single unitary piece of material of the conductive pattern 16x that is located between at least two unit pixels UP of a given (e.g., same) pixel group GP in the first and/or second directions X and/or Y and where the second conductive pattern 16b is a second portion of the single unitary piece of material of the conductive pattern 16x that is located between at least two unit pixels UP of separate (e.g., different) pixel groups GP in the first and/or second directions X and/or Y).

For example, referring to FIGS. 4 and 5A, the second filling insulation pattern 12b, the second separation insulating pattern 14b, and second conductive pattern 16b of a given second pixel separation portion DTI2 associated with a given pixel group GP may include (e.g., may be defined as) portions of the filling insulation pattern 12x, the separation insulating pattern 14x, and the conductive pattern 16x that are located within a region G that is defined, in the first and second directions X and Y, by outermost boundaries (e.g., outermost sidewalls) of the unit pixels UP of the given pixel group GP in the first and second directions X and Y.

In some example embodiments, the first and second filling insulation patterns 12a and 12b may be included in separate, respective (e.g., different) pieces of material. In some example embodiments, the first and second separation insulating patterns 14a and 14b may be included in separate, respective (e.g., different) pieces of material. In some example embodiments, the first and second conductive patterns 16a and 16b may be included in separate, respective (e.g., different) pieces of material.

The first filling insulation pattern 12a, the first separation insulating pattern 14a, the second filling insulation pattern 12b and the second separation insulating pattern 14b may each be formed of (e.g., may each at least partially comprise) an insulating material having a refractive index different from that of the first substrate 1. For example, the first filling insulation pattern 12a, the first separation insulating pattern 14a, the second filling insulation pattern 12b and the second separation insulating pattern 14b may each include silicon oxide. The first conductive pattern 16a and the second conductive pattern 16b may be spaced apart from (e.g., isolated from direct contact with) the first substrate 1. The first conductive pattern 16a and the second conductive pattern 16b may each include a poly-silicon layer or silicon-germanium layer, which is doped with dopants. The dopants doped in the poly-silicon layer or silicon-germanium layer may be, for example, boron, phosphorus, or arsenic. In some example embodiments, the first conductive pattern 16a and the second conductive pattern 16b (e.g., the conductive pattern 16x) may include a metal layer.

In the cross-sectional view of FIG. 5A, the first separation insulating pattern 14a may have the same thickness (e.g., a first thickness T1, which may be a first thickness T1 in the first direction X) as the second separation insulating pattern 14b. In the plan view of FIG. 4, the first thickness T1 (which may be a first thickness T1 in the first direction X) of each of the first and second separation insulating patterns 14a and 14b may be substantially constant regardless of a position of the first thickness T1 in a vertical direction that is perpendicular to the first direction X (e.g., the third direction Z).

The first conductive pattern 16a may have a third width W3 in the first direction X. The second conductive pattern 16b may have a fourth width W4 in the first direction X. The fourth width W4 may be smaller than the third width W3. In a case in which the first conductive pattern 16a and the second conductive pattern 16b are formed of poly-silicon, the poly-silicon may absorb light. In some example embodiments of the inventive concepts, the second conductive pattern 16b having the fourth width W4 which is relatively small may be disposed between the first to fourth unit pixels UP(1) to UP(4) constituting one pixel group GP to prevent/minimize/reduce absorption of incident light in the one pixel group GP. Thus, the amount of light received in the image sensor may be increased, quantum efficiency (QE) may be increased, and photosensitivity may be improved, thereby improving the image-sensing performance of the image sensor 500. In addition as a result, an auto-focus function may be improved, thereby improving the image-sensing performance of the image sensor 500. As a result, clear image quality of the image sensor may be realized, thereby improving the image-sensing performance of the image sensor 500.

The first filling insulation pattern 12a may have the third width W3 in the first direction X. The second filling insulation pattern 12b may have the fourth width W4 in the first direction X.

In the plan view of FIG. 4, the first and third unit pixels UP(1) and UP(3) may be arranged in a third direction Z intersecting (e.g., extending perpendicular to) both the first and second directions X and Y. The second pixel separation portion DTI2 may further include a third conductive pattern 16p disposed between the first and third unit pixels UP(1) and UP(3). The third conductive pattern 16p may also be disposed between the second and fourth unit pixels UP(2) and UP(4). In other words, the third conductive pattern 16p may be disposed at a center of each of the pixel groups GP. The third conductive pattern 16p may have a rhombus shape when viewed in a plan view. The third conductive pattern 16p may be disposed between the second conductive patterns 16b and may connect them (e.g., the second conductive patterns 16b that the third conductive pattern 16p is between). The third conductive pattern 16p may have a ninth width W9 (see FIG. 4) in the third direction Z. The ninth width W9 may be equal to or greater than the fourth width W4. The third conductive pattern 16p may be a portion of the conductive pattern 16x (e.g., such that the conductive pattern 16x extends continuously from the portion that defines the first conductive pattern 16a to a portion that defines the third conductive pattern 16p through a portion that defines the second conductive pattern 16b) or may be a separate piece of material from the conductive pattern 16x.

As shown, the third direction Z may be understood to extend perpendicular to at least one of the first surface 1a or the second surface 1b of the first substrate 1 and in some example embodiments may be referred to as extending perpendicular to the first substrate 1 based on extending perpendicular to at least one of the first surface 1a or the second surface 1b of the first substrate 1. Accordingly, the third direction Z may be referred to interchangeably as a vertical direction. As further noted above, the third direction Z may be understood to extend perpendicular to one or both of the first direction X and/or the second direction Y.

A first fixed charge layer 24 may be disposed on the second surface 1b of the first substrate 1. The first fixed charge layer 24 may be in contact with the second surface 1b of the first substrate 1. The first fixed charge layer 24 may be formed of a single layer or multi-layer including at least one of a metal oxide layer containing insufficient oxygen in terms of a stoichiometric ratio or a metal fluoride layer containing insufficient fluorine in terms of a stoichiometric ratio. Thus, the first fixed charge layer 24 may have negative fixed charges. The first fixed charge layer 24 may be formed of a single layer or multi-layer including a metal oxide layer and/or metal fluoride layer including at least one of hafnium (Hf), zirconium (Zr), aluminum (Al), tantalum (Ta), titanium (Ti), yttrium (Y), or a lanthanoid. For example, the first fixed charge layer 24 may include a hafnium oxide layer and/or an aluminum oxide layer. A dark current and a white spot may be reduced, minimized, or prevented by the first fixed charge layer 24.

A second fixed charge layer 42 and a first protective layer 44 may be sequentially stacked on the first fixed charge layer 24. The second fixed charge layer 42 may include a single layer or multi-layer including at least one of a metal oxide layer or a metal fluoride layer. For example, the second fixed charge layer 42 may include a hafnium oxide layer and/or an aluminum oxide layer. The second fixed charge layer 42 may reinforce the first fixed charge layer 24 or may function as an adhesive layer. For example, the first protective layer 44 may include at least one of PETEOS, SiOC, SiO₂, or SiN. The first protective layer 44 may function as an anti-reflection layer and/or a planarization layer.

Referring to FIGS. 4 and 5A, in the edge region EG, a connection contact BCA may penetrate the first protective layer 44, the second fixed charge layer 42, the first fixed charge layer 24 and a portion of the first substrate 1 and may be in contact with the first conductive pattern 16a and the first separation insulating pattern 14a. The connection contact BCA may be disposed in a third trench 46. The connection contact BCA may include a first diffusion barrier pattern 48g conformally covering an inner sidewall and a bottom surface of the third trench 46, a first metal pattern 52 on the first diffusion barrier pattern 48g, and a second metal pattern 54 filling the third trench 46. For example, the first diffusion barrier pattern 48g may include titanium. The first metal pattern 52 may include, for example, tungsten. The second metal pattern 54 may include, for example, aluminum. The first diffusion barrier pattern 48g and the first metal pattern 52 may extend onto the first protective layer 44 so as to be electrically connected to other interconnection lines or vias/contacts.

In the pixel array region APS, first and second light blocking patterns 48a and 48b may be disposed on the first protective layer 44. First and second low-refractive patterns 50a and 50b may be disposed on the first and second light blocking patterns 48a and 48b, respectively. The first light blocking pattern 48a and the first low-refractive pattern 50a may overlap with the first pixel separation portion DTI1 and may have the same shape as the first pixel separation portion DTI1 when viewed in a plan view. In other words, the first light blocking pattern 48a and the first low-refractive pattern 50a may surround each of the pixel groups GP(1) to GP(4) when viewed in a plan view. The second light blocking pattern 48b and the second low-refractive pattern 50b may overlap with the second pixel separation portion DTI2 and may have the same shape as the second pixel separation portion DTI2 when viewed in a plan view. The second light blocking pattern 48b and the second low-refractive pattern 50b may be disposed between the first to fourth unit pixels UP(1) to UP(4) in each of the pixel groups GP(1) to GP(4) when viewed in a plan view.

Sidewalls of the first light blocking pattern 48a and the first low-refractive pattern 50a may be aligned with each other. Each of the first light blocking pattern 48a and the first low-refractive pattern 50a may have a fifth width W5 in the first direction X. Sidewalls of the second light blocking pattern 48b and the second low-refractive pattern 50b may be aligned with each other. Each of the second light blocking pattern 48b and the second low-refractive pattern 50b may have a sixth width W6 in the first direction X. The sixth width W6 may be equal to or less than the fifth width W5. When the sixth width W6 is less than the fifth width W5, the amount of light incident into the first to fourth unit pixels UP(1) to UP(4) constituting one pixel group GP may be relatively increased. Thus, the amount of light received in the image sensor may be increased, quantum efficiency (QE) may be increased, and photosensitivity may be improved, thereby improving the image sensing performance of the image sensor 500.

The first light blocking pattern 48a and the second light blocking pattern 48b may have the same material and the same thickness as the first diffusion barrier pattern 48g. The first light blocking pattern 48a and the second light blocking pattern 48b may include, for example, titanium.

The first low-refractive pattern 50a and the second low-refractive pattern 50b may have the same thickness and may include the same organic material. The first low-refractive pattern 50a and the second low-refractive pattern 50b may have a refractive index that is less (e.g., smaller) than that of color filters CF1 and CF2. For example, the first low-refractive pattern 50a and the second low-refractive pattern 50b may have a refractive index of about 1.3 or less (e.g., about 0.01 to about 1.3, about 0.1 to about 1.3, about 0.5 to about 1.3, etc.). The first and second light blocking patterns 48a and 48b and the first and second low-refractive patterns 50a and 50b may reduce, minimize, or prevent cross-talk between the unit pixels UP adjacent to each other.

A second protective layer 56 may be stacked on the first protective layer 44. The second protective layer 56 may conformally cover the first and second light blocking patterns 48a and 48b, the first and second low-refractive patterns 50a and 50b, and the connection contact BCA. In the pixel array region APS, color filters CF1 and CF2 may be disposed between the first and second low-refractive patterns 50a and 50b. Each of the color filters CF1 and CF2 may have (e.g., may be configured to selectively transmit light of) a blue color, a green color, or a red color. In some example embodiments, each of the color filters CF1 and CF2 may have (e.g., may be configured to selectively transmit light of) another color such as a cyan color, a magenta color, or a yellow color.

In some example embodiments, one color filter may be disposed on one pixel group GP. In the image sensor according to some example embodiments, the color filters CF1 and CF2 may be arranged in the form of a 2×2 tetra pattern. In other words, a first color filter CF1 may be disposed on the second pixel group GP(2). A second color filter CF2 may be disposed on the first, third or fourth pixel group GP(1), GP(3) or GP(4).

In the edge region EG, a first optical black pattern CFB may be disposed on the second protective layer 56. For example, the first optical black pattern CFB may include the same material as the blue color filter.

In the pixel array region APS, micro lenses ML may be disposed on the color filters CF1 and CF2. Edges of the micro lenses ML may be in contact with each other and may be connected to each other. In some example embodiments, one micro lens ML may be disposed on one pixel group GP. In other words, the one micro lens ML may cover the first to fourth unit pixels UP(1) to UP(4) adjacent to each other. In the plan view of FIG. 4, the second pixel separation portion DTI2 may pass through a center of the micro lens ML.

In the edge region EG, a lens residual layer MLR may be disposed on the first optical black pattern CFB. The lens residual layer MLR may include the same material as the micro lenses ML. The image sensor 500 may be an auto-focus image sensor.

A negative bias voltage may be applied to the first and second conductive patterns 16a and 16b through the connection contact BCA. The first and second conductive patterns 16a and 16b may function as a common bias line. As a result, it is possible to capture holes existing on a surface of the first substrate 1 which is in contact with the first and second pixel separation portions DTI1 and DTI2, and thus a dark current may be reduced or minimized.

FIG. 5B is a cross-sectional view taken along the line A-A′ of FIG. 3 according to some example embodiments of the inventive concepts.

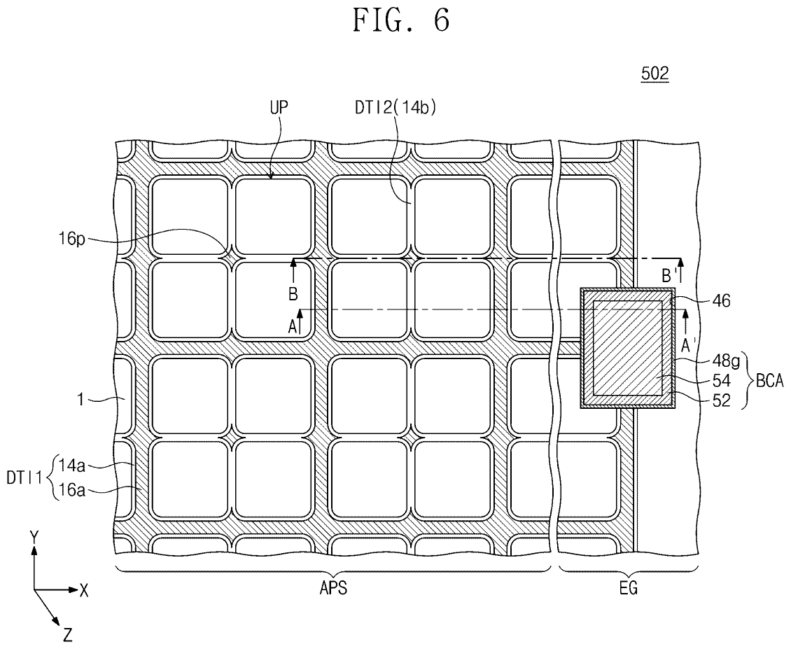

Referring to FIGS. 3 and 5B, in an image sensor 501 according to some example embodiments, a second pixel separation portion DTI2 may exclude the second conductive pattern 16b and the second filling insulation pattern 12b of FIG. 5A. The second pixel separation portion DTI2 may further include the third conductive pattern 16p like FIG. 6, and in some example embodiments, the third conductive pattern 16p may not be connected to the second conductive pattern 16b but may be separated. The second pixel separation portion DTI2 may include a void region VD located in a second separation insulating pattern 14b. For example, the second separation insulating pattern 14b may include one or more inner surfaces 14bs defining a void region VD within an interior of the second separation insulating pattern 14b. In some example embodiments, the void region VD may be a seam. A maximum width of the void region VD may be a fourth width W4. The fourth width W4 may be less than the third width W3 of the first conductive pattern 16a of the first pixel separation portion DTI1. The second separation insulating pattern 14b may have a first thickness T1 at a position at which the void region VD has the maximum width W4. The first thickness T1 may be equal to the thickness of the first separation insulating pattern 14a of the first pixel separation portion DTI1. A planar shape of the void region VD may be the same/similar as that of the second conductive pattern 16b of FIG. 4. Other structures and components may be the same/similar as described with reference to FIGS. 3 to 5A.

In the image sensor 501 of FIG. 5B, the second conductive pattern 16b may not exist between the first to fourth unit pixels UP(1) to UP(4) constituting each of the pixel groups GP (e.g., the second conductive pattern 16b may be omitted), and thus it is possible to reduce, minimize, or prevent light incident into each of the pixel groups GP from being absorbed into the second conductive pattern 16b. As a result, the amount of light received in the image sensor may be increased, quantum efficiency (QE) may be increased, and photosensitivity may be improved, thereby improving image-generating performance of the image sensor 501. In addition as a result, an auto-focus function may be improved, thereby improving image-generating performance of the image sensor 501.

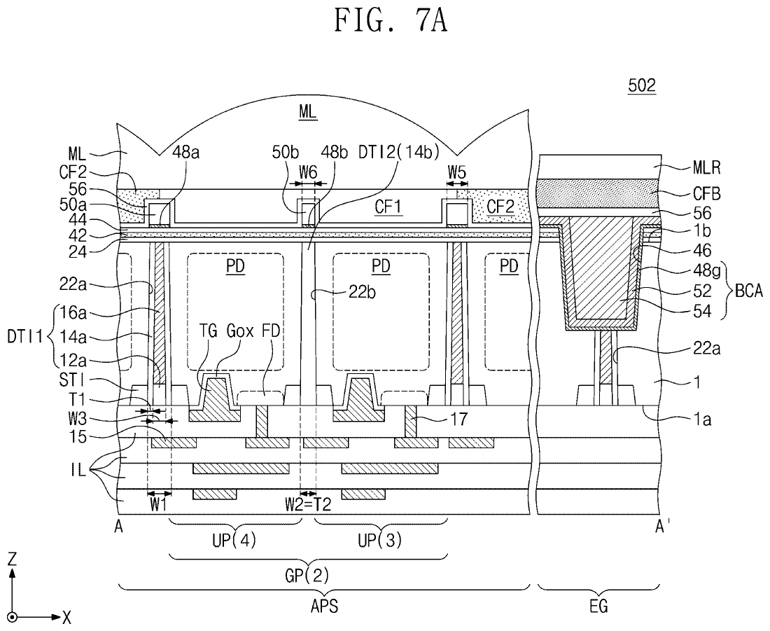

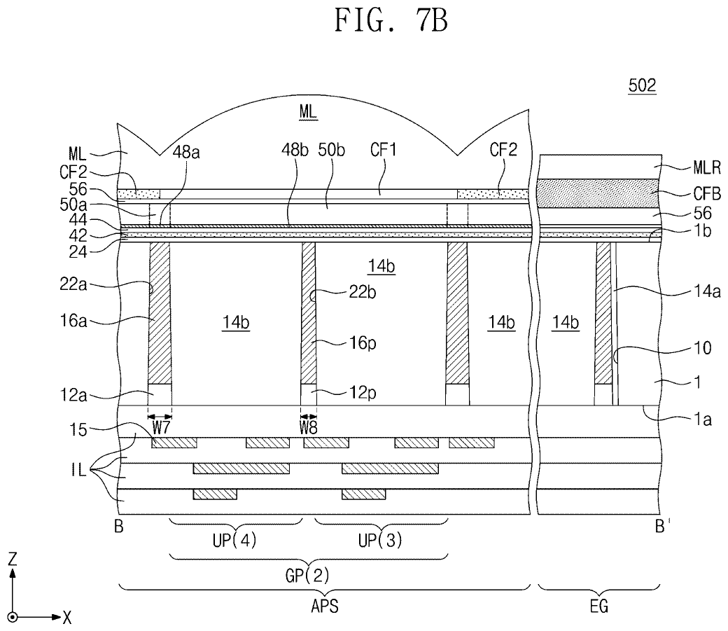

FIG. 6 is a plan view illustrating an image sensor including a pixel separation portion according to some example embodiments of the inventive concepts. FIG. 7A is a cross-sectional view taken along a line A-A′ of FIG. 6 according to some example embodiments of the inventive concepts. FIG. 7B is a cross-sectional view taken along a line B-B′ of FIG. 6 according to some example embodiments of the inventive concepts.

Referring to FIGS. 6, 7A and 7B, in an image sensor 502 according to some example embodiments, a second pixel separation portion DTI2 may be formed of a second separation insulating pattern 14b. Here, a second thickness T2 (e.g., in the first direction X) of the second separation insulating pattern 14b may be equal to the second width W2 of the second pixel separation portion DTI2 or the second trench 22b. The second thickness T2 (e.g., in the first direction X) may be greater than the first thickness T1 (e.g., in the first direction X) of the first separation insulating pattern 14a of the first pixel separation portion DTI1. The second pixel separation portion DTI2 may further include the third conductive pattern 16p, and in some example embodiments, the third conductive pattern 16p may be surrounded by the second separation insulating pattern 14b and thus may be separated. A sidewall of the first pixel separation portion DTI1 may have an uneven structure. In the cross-sectional view of FIG. 7A, the first conductive pattern 16a of the first pixel separation portion DTI1 may have the third width W3 in the first direction X. In the cross-sectional view of FIG. 7B, the first conductive pattern 16a of the first pixel separation portion DTI1 may have a seventh width W7 in the first direction X. The seventh width W7 may be greater than the third width W3. In the cross-sectional view of FIG. 7B, the third conductive pattern 16p may have an eighth width W8. The eighth width W8 may be less than the seventh width W7.

The second pixel separation portion DTI2 may further include a third filling insulation pattern 12p on the third conductive pattern 16p. The third filling insulation pattern 12p may include the same material as the first filling insulation pattern 12a. The third filling insulation pattern 12p may have a rhombus shape when viewed in a plan view. The third filling insulation pattern 12p may have the eighth width W8. Other structures and components may be the same/similar as described with reference to FIGS. 3 to 5A.

In the image sensor 502 of FIG. 7A, the second conductive pattern 16b may not exist between the first to fourth unit pixels UP(1) to UP(4) constituting each of the pixel groups GP, and thus it is possible to reduce, minimize, or prevent light incident into each of the pixel groups GP from being absorbed into the second conductive pattern 16b. As a result, the amount of light received in the image sensor may be increased, quantum efficiency (QE) may be increased, and photosensitivity may be improved. In addition, an auto-focus function may be improved.

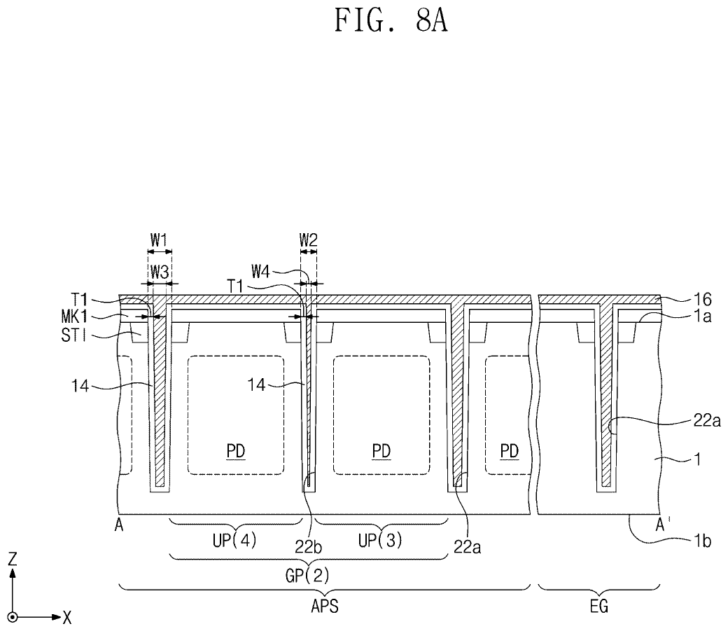

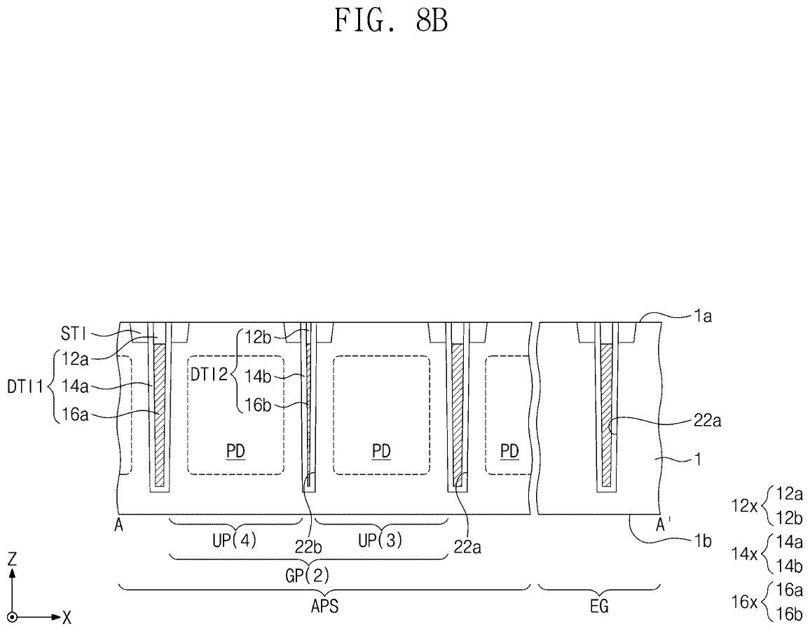

FIGS. 8A and 8B are cross-sectional views illustrating a method of manufacturing an image sensor having the cross section of FIG. 5A.

Referring to FIG. 8A, a first substrate 1 including a pixel array region APS and an edge region EG may be prepared. An ion implantation process may be performed into the first substrate 1 to form photoelectric conversion portions PD. A device separation portion STI may be formed in a first surface 1a of the first substrate 1 to define active regions. The device separation portion STI may be formed by a shallow trench separation process. A first mask pattern MK1 may be formed on the first surface 1a of the first substrate 1. The device separation portion STI and a portion of the first substrate 1 may be etched using the first mask pattern MK1 as an etch mask to form first and second trenches 22a and 22b. In some example embodiments, the first trenches 22a may be formed to have a first width W1. The second trenches 22b may be formed to have a second width W2 smaller than the first width W1.

A separation insulating layer 14 with a first thickness T1 may be conformally formed on the first surface 1a of the first substrate 1. Thus, the separation insulating layer 14 may have the first thickness T1 in the first and second trenches 22a and 22b. The first thickness T1 may be less than ½ of the second width W2. A conductive layer 16 may be formed on the separation insulating layer 14 to fill the first and second trenches 22a and 22b. The conductive layer 16 may have a third width W3 in the first trench 22a. The conductive layer 16 may have a fourth width W4 in the second trench 22b.

Referring to FIG. 8B, an etch-back process may be performed on the conductive layer 16 to remove the conductive layer 16 on the first surface 1a of the first substrate 1 and to form the conductive pattern 16x that includes the first and second conductive patterns 16a and 16b in the first and second trenches 22a and 22b, respectively. In the etch-back process, top surfaces of the first and second conductive patterns 16a and 16b may be formed to be lower than the first surface 1a of the first substrate 1. Thereafter, a filling insulation layer may be formed to fill upper portions of the first and second trenches 22a and 22b. Subsequently, a polishing process may be performed to remove the separation insulating layer 14 and the filling insulation layer on the first surface 1a of the first substrate 1 and to form the separation insulating pattern 14x that includes the first and second separation insulating patterns 14a and 14b and the filling insulation pattern 12x that includes the first and second filling insulation patterns 12a and 12b in the first and second trenches 22a and 22b, respectively. Thus, first and second pixel separation portions DTI1 and DTI2 may be formed.

Subsequently, other components of FIGS. 3 to 5A may be formed through general processes. However, the widths W5 and W6 of the first and second light blocking patterns 48a and 48b and the first and second low-refractive patterns 50a and 50b may be formed to be different from each other like FIG. 5A.

In some example embodiments, in the step of FIG. 8A, the second width W2 may be narrow, and thus the separation insulating layer 14 may close an entrance of the second trench 22b. In this case, the void region VD may be formed in the second trench 22b like FIG. 5B, or the second trench 22b may be filled with the separation insulating layer 14 without the void region VD like FIG. 7A. In this case, the conductive layer 16 may not enter the second trench 22b. Thus, the image sensor of FIG. 5B or 7A may be manufactured.

Poly-silicon of a conductive pattern may absorb light, and thus as the amount of poly-silicon is increased, a loss of incident light may be increased by absorption of poly-silicon to deteriorate sensitivity of an image sensor. If both first and second pixel separation portions are replaced with insulating structures to reduce, minimize, or prevent this, a negative voltage may not be applied to a conductive pattern, and thus it may be difficult to reduce or minimize a dark current.

However, according to some example embodiments of the inventive concepts, the widths of the first and second pixel separation portions DTI1 and DTI2 may be different from each other, and thus the structures/composition ratios of the first and second pixel separation portions DTI1 and DTI2 may be different from each other. In other words, the second pixel separation portion DTI2 overlapping one micro lens may have a small amount of poly-silicon or exclude poly-silicon to improve photosensitivity of the image sensor including same, and the first pixel separation portion DTI1 located at a boundary of the micro lenses may include relatively wide poly-silicon (i.e., the first conductive pattern 16a) to reduce or minimize the dark current by applying a negative voltage thereto, thereby improving image-generating performance of the image sensor.

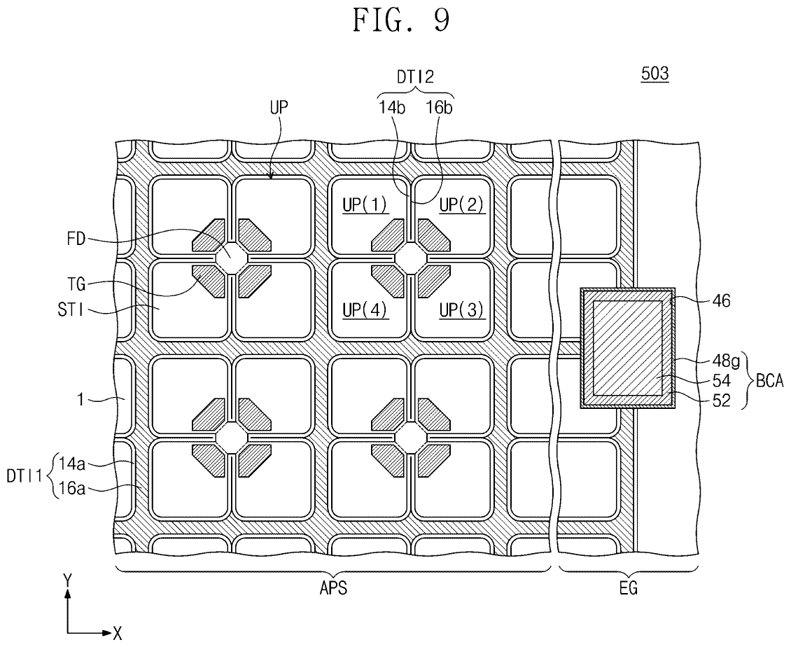

FIG. 9 is a plan view illustrating an image sensor according to some example embodiments of the inventive concepts.

Referring to FIG. 9, a second pixel separation portion DTI2 of an image sensor 503 according to some example embodiments may not include the third conductive pattern 16p. In other words, the third conductive pattern 16p may not be disposed at a center of each of the pixel groups GP. A floating diffusion region FD may be disposed in the first substrate 1 at the center of each of the pixel groups GP. The second pixel separation portion DTI2 may not exist at the center of each of the pixel groups GP. In each of the pixel groups GP, transfer gates TG may be disposed on the first to fourth unit pixels UP(1) to UP(4) and may surround the floating diffusion region FD in a plan view. The first to fourth unit pixels UP(1) to UP(4) of each of the pixel groups GP may share the floating diffusion region FD. Other structures and components may be the same/similar as described with reference to FIGS. 3 to 5A.

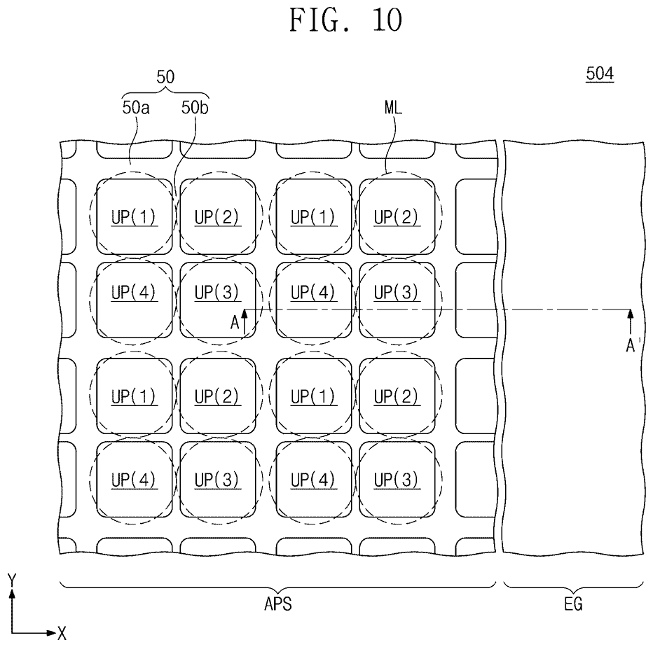

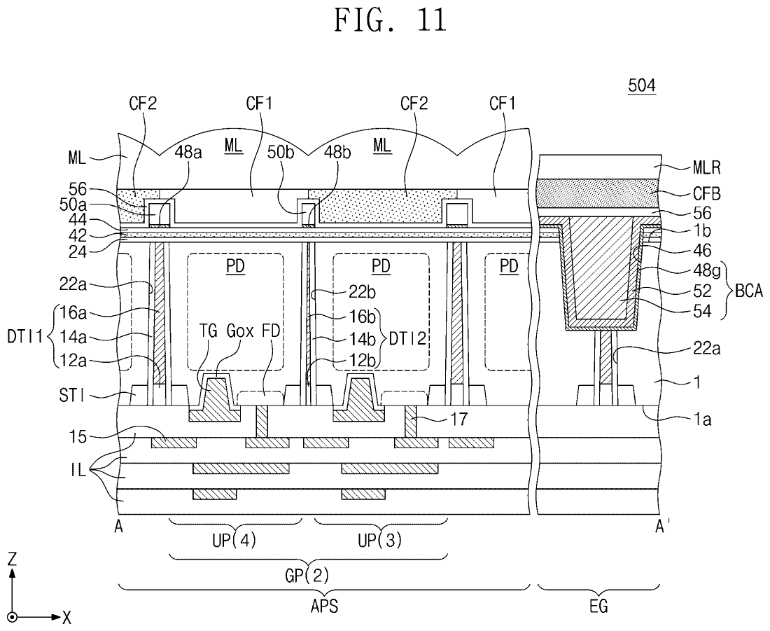

FIG. 10 is a plan view illustrating an image sensor according to some example embodiments of the inventive concepts. FIG. 11 is a cross-sectional view taken along a line A-A′ of FIG. 10.

Referring to FIGS. 10 and 11, in an image sensor 504 according to some example embodiments, micro lenses ML may be disposed on the unit pixels UP, respectively (in one-to-one correspondence). In other words, one micro lens ML may be disposed on one unit pixel UP. In addition, color filters CF1 and CF2 may be disposed on the unit pixels UP, respectively (in one-to-one correspondence). In other words, one color filter CF1 or CF2 may be disposed on one unit pixel UP. Other structures and components may be the same/similar as described with reference to FIGS. 3 to 7B.

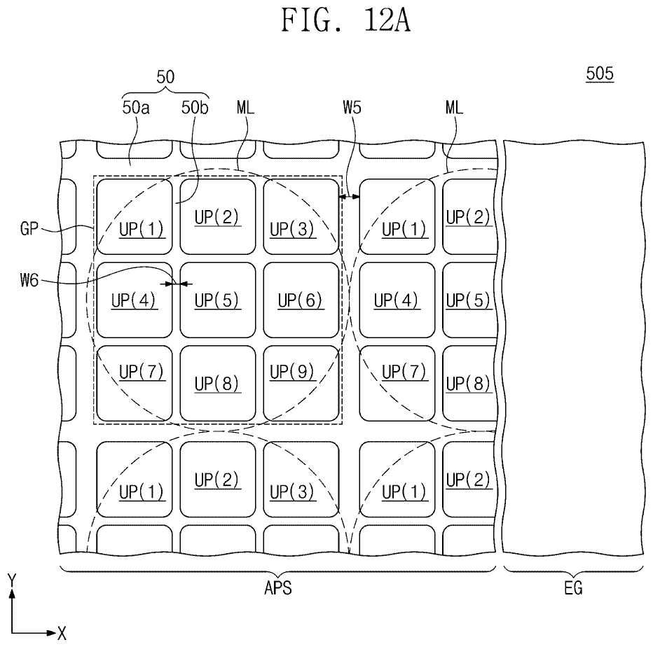

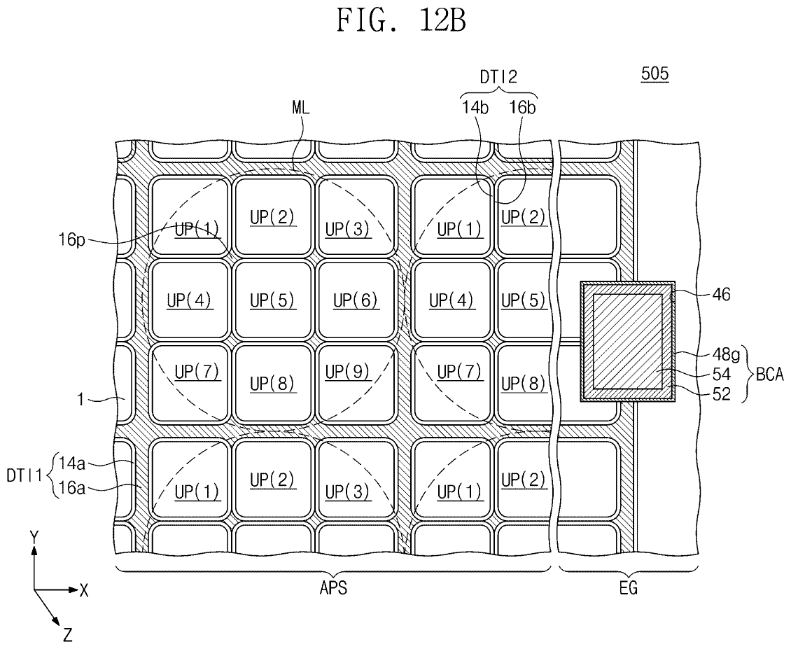

FIG. 12A is a plan view illustrating an image sensor having a low-refractive pattern according to some example embodiments of the inventive concepts. FIG. 12B is a plan view illustrating an image sensor having a pixel separation portion according to some example embodiments of the inventive concepts.

Referring to FIGS. 12A and 12B, in an image sensor 505 according to some example embodiments, each of pixel groups GP may include nine unit pixels UP(1) to UP(9) constituting three rows and three columns. One micro lens ML may be disposed on one pixel group GP. In other words, the one micro lens ML may cover all of the nine unit pixels UP(1) to UP(9) constituting three rows and three columns. One color filter CF1 or CF2 may be disposed on the one pixel group GP. In the image sensor 505 according to some example embodiments, the color filters CF1 and CF2 may be arranged in the form of a 3×3 Nona pattern. The first pixel separation portion DTI1 may surround the pixel group GP when viewed in a plan view. The second pixel separation portion DTI2 may extend from the sidewall of the first pixel separation portion DTI1 and may be disposed between the unit pixels UP(1) to UP(9). In FIG. 12B, four third conductive patterns 16p may be disposed in each of the pixel groups GP. A sixth width W6 of the second light blocking patterns 48b and the second low-refractive patterns 50b which overlap with the second pixel separation portion DTI2 may be less than a fifth width W5 of the first light blocking patterns 48a and the first low-refractive patterns 50a which overlap with the first pixel separation portion DTI1. Other structures and components may be the same/similar as described above.

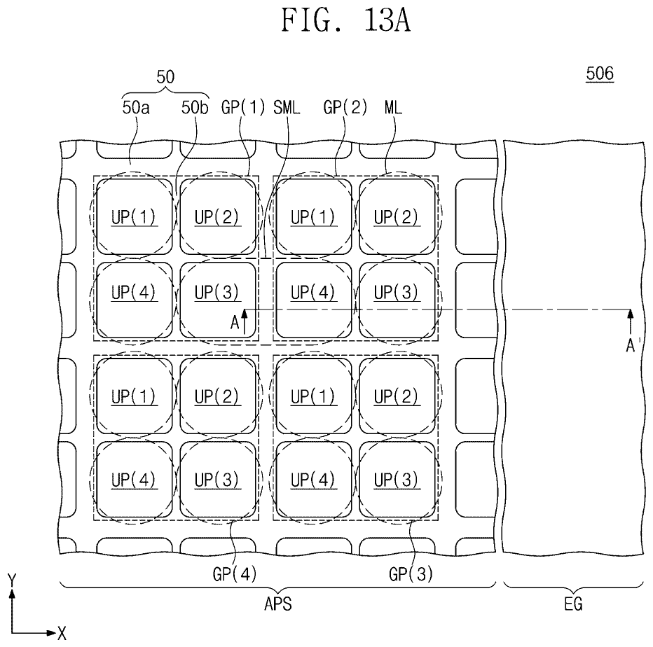

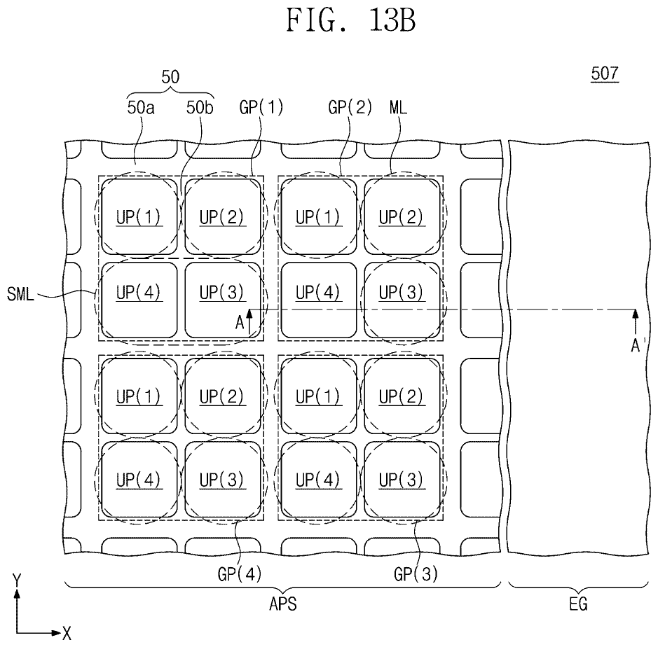

FIGS. 13A and 13B are plan views illustrating image sensors having low-refractive patterns according to some example embodiments of the inventive concepts.

Referring to FIG. 13A, an image sensor 506 according to some example embodiments may include a super micro lens SML. More particularly, planar/sectional shapes of first and second pixel separation portions DTI1 and DTI2, a first light blocking pattern 48a, a first low-refractive pattern 50a, a second light blocking pattern 48b and a second low-refractive pattern 50b may be the same/similar as described with reference to FIGS. 3 to 7B. Micro lenses ML may be disposed on the first to fourth unit pixels UP(1) to UP(4), respectively. However, the third unit pixel UP(3) of the first pixel group GP(1) and the fourth unit pixel UP(4) of the second pixel group GP(2) adjacent thereto may be covered with a single super micro lens SML. The first pixel separation portion DTI1, the first light blocking pattern 48a and/or the first low-refractive pattern 50a may be disposed between the third unit pixel UP(3) of the first pixel group GP(1) and the fourth unit pixel UP(4) of the second pixel group GP(2) adjacent thereto when viewed in a plan view.

The third unit pixel UP(3) of the first pixel group GP(1) and the fourth unit pixel UP(4) of the second pixel group GP(2) adjacent thereto, which are covered with the super micro lens SML, may be used as auto-focus (AF) pixels for an auto-focus function. Other first to fourth unit pixels UP(1) to UP(4) may be used as image pixels for sensing an image. Other components may be the same/similar as described above.

In some example embodiments, referring to FIG. 13B, in an image sensor 507 according to some example embodiments, the super micro lens SML may cover both the third and fourth unit pixels UP(3) and UP(4) of the first pixel group GP(1). The second pixel separation portion DTI2, the second light blocking pattern 48b and/or the second low-refractive pattern 50b may be disposed between the third and fourth unit pixels UP(3) and UP(4) of the first pixel group GP(1) when viewed in a plan view. The third and fourth unit pixels UP(3) and UP(4) of the first pixel group GP(1), which are covered with the super micro lens SML, may be used as auto-focus (AF) pixels for the auto-focus function. Other first to fourth unit pixels UP(1) to UP(4) may be used as image pixels for sensing an image. Other components may be the same/similar as described with reference to FIG. 13A.

FIG. 14 is a cross-sectional view illustrating an image sensor according to some example embodiments of the inventive concepts.

Referring to FIG. 14, an image sensor 508 according to some example embodiments may have a structure in which a first sub-chip CH1 and a second sub-chip CH2 are bonded to each other. For example, the first sub-chip CH1 may perform an image sensing function. For example, the second sub-chip CH2 may include circuits for driving the first sub-chip CH1 and/or for storing electrical signals generated from the first sub-chip CH1.

The second sub-chip CH2 may include a second substrate 100, a plurality of transistors TR disposed on the second substrate 100, a second interlayer insulating layer 110 covering the second substrate 100, and second interconnection lines 112 disposed in the second interlayer insulating layer 110. The second interlayer insulating layer 110 may have a single-layered or multi-layered structure including at least one of a silicon oxide layer, a silicon nitride layer, a silicon oxynitride layer, or a porous insulating layer. The first sub-chip CH1 and the second sub-chip CH2 may be bonded to each other. Thus, a first interlayer insulating layer IL of the first sub-chip CH1 may be in contact with the second interlayer insulating layer 110.

The first sub-chip CH1 may include a first substrate 1 including a pad region PAD, a connection region CNR, an optical black region OB, and a pixel array region APS. The first sub-chip CH1 in the pixel array region APS and a portion of the connection region CNR may have the same/similar structure as described with reference to FIGS. 3 to 13B. In other words, the pixel array region APS may include a plurality of unit pixels UP. First and second pixel separation portions DTI1 and DTI2 may be disposed in the first substrate 1 of the pixel array region APS to separate the unit pixels UP from each other. A device separation portion STI adjacent to a first surface 1a may be disposed in the first substrate 1. A photoelectric conversion portion PD may be disposed in the first substrate 1 in each of the unit pixels UP. A transfer gate TG may be disposed on the first surface 1a of the first substrate 1 of each of the unit pixels UP. A floating diffusion region FD may be disposed in the first substrate 1 at a side of the transfer gate TG. The first surface 1a may be covered with the first interlayer insulating layers IL.

Light may not be incident into the first substrate 1 of the optical black region OB. The first and second pixel separation portions DTI1 and DTI2 may extend into the optical black region OB to separate a first black pixel UPO1 and a second black pixel UPO2 from each other. The photoelectric conversion portion PD may be disposed in the first substrate 1 of the first black pixel UPO1. The photoelectric conversion portion PD may not exist in the first substrate 1 of the second black pixel UPO2. A transfer gate TG and a floating diffusion region FD may be disposed in each of the first and second black pixels UPO1 and UPO2. The first black pixel UPO1 may sense the amount of charges generated from the photoelectric conversion portion PD into which light is not incident, and thus the first black pixel UPO1 may provide a first reference charge amount. The first reference charge amount may be used as a relative reference value when the amounts of charges generated from the unit pixels UP are calculated. The second black pixel UPO2 may sense the amount of charges generated in a state in which the photoelectric conversion portion PD does not exist, and thus the second black pixel UPO2 may provide a second reference charge amount. The second reference charge amount may be used as data for removing process noise.

A first fixed charge layer 24, a second fixed charge layer 42, a first protective layer 44 and a second protective layer 56 may extend onto a second surface 1b of the optical black region OB, the connection region CNR and the pad region PAD. The edge region EG described with reference to FIGS. 3 to 13B may correspond to a portion of the connection region CNR of FIG. 14.

In the connection region CNR, a connection contact BCA may penetrate the first protective layer 44, the second fixed charge layer 42, the first fixed charge layer 24 and a portion of the first substrate 1 so as to be in contact with the first conductive pattern 16a of the first pixel separation portion DTI1. The connection contact BCA may be disposed in a third trench 46. The connection contact BCA may include a first diffusion barrier pattern 48g conformally covering an inner sidewall and a bottom surface of the third trench 46, a first metal pattern 52 on the first diffusion barrier pattern 48g, and a second metal pattern 54 filling the third trench 46.

A portion of the first diffusion barrier pattern 48g may extend onto the first protective layer 44 of the optical black region OB to provide a third optical black pattern 48c. A portion of the first metal pattern 52 may extend onto the third optical black pattern 48c of the optical black region OB to provide a second optical black pattern 52a. A second protective layer 56 may cover the second optical black pattern 52a and the connection contact BCA. A first optical black pattern CFB may be located on the second protective layer 56 in the optical black region OB and the connection region CNR.

In the connection region CNR, a first via V1 may be disposed at a side of the connection contact BCA. The first via V1 may be referred to as a back bias stack via. The first via V1 may penetrate the first protective layer 44, the second fixed charge layer 42, the first fixed charge layer 24, the first substrate 1, the first interlayer insulating layers IL and a portion of the second interlayer insulating layer 110 so as to be in contact with both at least one of the first interconnection lines 15 and at least one of the second interconnection lines 112.

The first via V1 may be disposed in a first via hole H1. The first via V1 may include a second diffusion barrier pattern 48d and a first via pattern 52b on the second diffusion barrier pattern 48d. The second diffusion barrier pattern 48d may be connected to the first diffusion barrier pattern 48g. The first via pattern 52b may be connected to the first metal pattern 52. The connection contact BCA may be connected to at least one of the first interconnection lines 15 and at least one of the second interconnection lines 112 through the first via V1.

Each of the second diffusion barrier pattern 48d and the first via pattern 52b may conformally cover an inner surface of the first via hole H1. The second diffusion barrier pattern 48d and the first via pattern 52b may not completely fill the first via hole H1. A first low-refractive index residual layer 50g may fill the first via hole H1. A color filter residual layer CFR may be disposed on the first low-refractive index residual layer 50g.

An external connection pad 62 and a second via V2 which are connected to each other may be disposed in the pad region PAD. The external connection pad 62 may penetrate the first protective layer 44, the second fixed charge layer 42, the first fixed charge layer 24, and a portion of the first substrate 1. The external connection pad 62 may be disposed in a fourth trench 60. The external connection pad 62 may include a third diffusion barrier pattern 48e and a first pad pattern 52c which sequentially and conformally cover an inner sidewall and a bottom surface of the fourth trench 60, and a second pad pattern 54a filling the fourth trench 60.

The second via V2 may penetrate the first protective layer 44, the second fixed charge layer 42, the first fixed charge layer 24, the first substrate 1, the first interlayer insulating layers IL and a portion of the second interlayer insulating layer 110 so as to be in contact with at least one of the second interconnection lines 112. The external connection pad 62 may be connected to at least one of the second interconnection lines 112 through the second via V2. The second via V2 may be disposed in a second via hole H2. The second via V2 may include a fourth diffusion barrier pattern 48f and a second via pattern 52d which sequentially and conformally cover an inner sidewall and a bottom surface of the second via hole H2. The fourth diffusion barrier pattern 48f and the second via pattern 52d may not completely fill the second via hole H2. A second low-refractive index residual layer 50c may fill the second via hole H2. A color filter residual layer CFR may be disposed on the second low-refractive index residual layer 50c.

The first and second light blocking patterns 48a and 48b, the first diffusion barrier pattern 48g, the third optical black pattern 48c and the second to fourth diffusion barrier patterns 48d to 48f may have the same thickness and the same material (e.g., titanium). The first metal pattern 52, the second optical black pattern 52a, the first via pattern 52b, the first pad pattern 52c and the second via pattern 52d may have the same thickness and the same material (e.g., tungsten). The second metal pattern 54 and the second pad pattern 54a may have the same material (e.g., aluminum).

The first and second low-refractive patterns 50a and 50b, the first low-refractive index residual layer 50g and the second low-refractive index residual layer 50c may have the same material. The color filter residual layer CFR may have the same color and material as one of the color filters CF1 and CF2.

The second protective layer 56 may extend into the pad region PAD and may have an opening exposing the second pad pattern 54a. A lens residual layer MLR may cover the optical black region OB, the connection region CNR and the pad region PAD. The lens residual layer MLR may have (e.g., may include one or more inner surfaces at least partially defining) an opening 35 exposing the second pad pattern 54a in the pad region PAD.

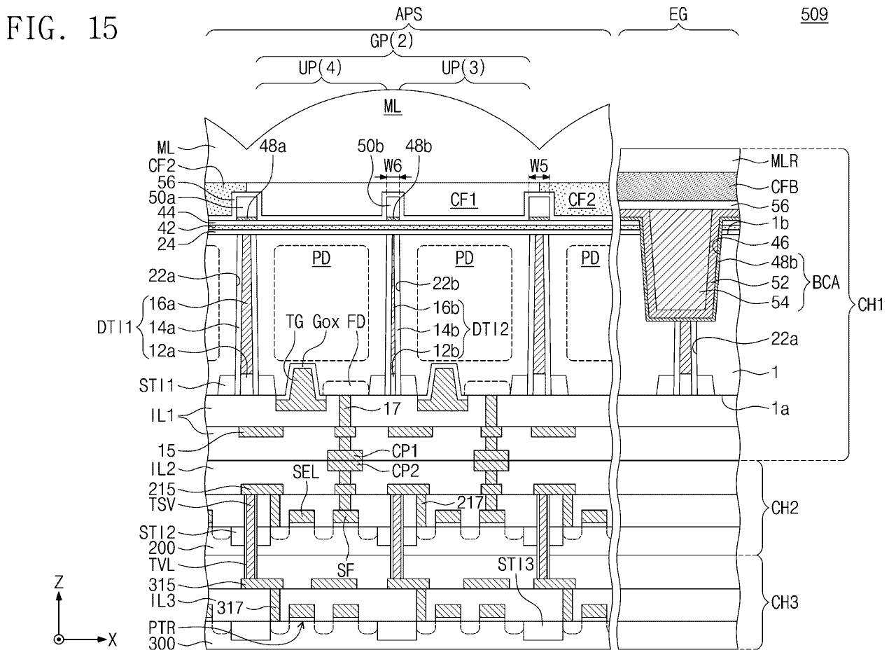

FIG. 15 is a cross-sectional view illustrating an image sensor according to some example embodiments of the inventive concepts.

Referring to FIG. 15, an image sensor 509 according to some example embodiments may have a structure in which first to third sub-chips CH1 to CH3 are stacked and are bonded to each other. For example, the first sub-chip CH1 may perform an image sensing function. The first sub-chip CH1 may be the same/similar as described with reference to FIGS. 3 to 13B. The first sub-chip CH1 may include transfer gates TG on the first surface 1a of the first substrate 1 and first interlayer insulating layers IL1 covering them. A first device separation portion STI1 may be disposed in the first substrate 1 to define active regions. A first conductive pad CP1 may be disposed in a lowermost first interlayer insulating layer IL1. The first conductive pad CP1 may include copper.

The second sub-chip CH2 may include a second substrate 200; selection gates SEL, source follower gates SF and reset gates (not shown) which are disposed on the second substrate 200; and second interlayer insulating layers IL2 covering them. A second device separation portion STI2 may be disposed in the second substrate 200 to define active regions. Second contacts 217 and second interconnection lines 215 may be disposed in the second interlayer insulating layers IL2. A second conductive pad CP2 may be disposed in an uppermost second interlayer insulating layer IL2. The second conductive pad CP2 may include copper. The second conductive pad CP2 may be in contact with the first conductive pad CP1. The source follower gates SF may be connected to floating diffusion regions FD of the first sub-chip CH1, respectively.

The third sub-chip CH3 may include a third substrate 300, peripheral transistors PTR disposed on the third substrate 300, and third interlayer insulating layers IL3 covering the peripheral transistors PTR. A third device separation portion STI3 may be disposed in the third substrate 300 to define active regions. Third contacts 317 and third interconnection lines 315 may be disposed in the third interlayer insulating layers IL3. An uppermost third interlayer insulating layer IL3 may be in contact with the second substrate 200. A through-electrode TSV may penetrate the second interlayer insulating layer IL2, the second device separation portion STI2, the second substrate 200 and the third interlayer insulating layer IL3 to connect the second interconnection line 215 to the third interconnection line 315. A sidewall of the through-electrode TSV may be surrounded by a via insulating layer TVL. The third sub-chip CH3 may include circuits for driving the first sub-chip CH1 and/or the second sub-chip CH2 and/or for storing electrical signals generated from the first sub-chip CH1 and/or the second sub-chip CH2.

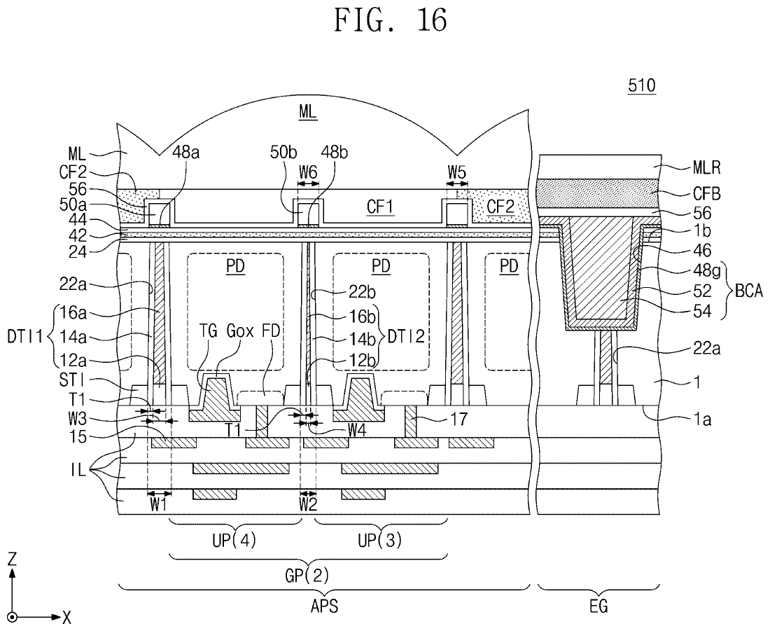

FIG. 16 is a cross-sectional view illustrating an image sensor according to some example embodiments of the inventive concepts.

Referring to FIG. 16, in an image sensor 510 according to some example embodiments, each of a first light blocking pattern 48a and a first low-refractive pattern 50a may have a fifth width W5 in the first direction X. Each of a second light blocking pattern 48b and a second low-refractive pattern 50b may have a sixth width W6 in the first direction X. The sixth width W6 may be equal to the fifth width W5.

Each of the first pixel separation portion DTI1 and the first trench 22a may have a first width W1 in the first direction X. Each of the second pixel separation portion DTI2 and the second trench 22b may have a second width W2 in the first direction X. The second width W2 may be less than the first width W1. The sixth width W6 may be equal to or different from the second width W2. The sixth width W6 may be greater than the second width W2. Other structures and components may be the same as described with reference to FIG. 5A.

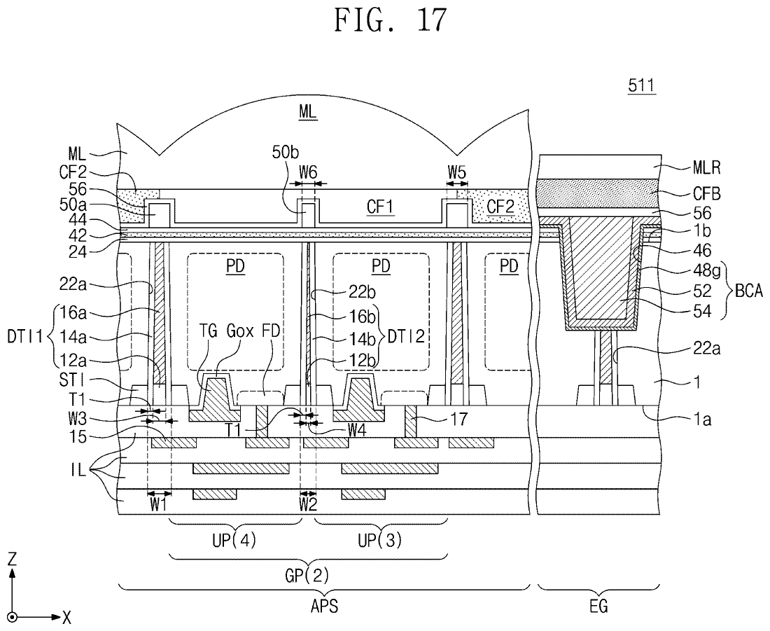

FIG. 17 is a cross-sectional view illustrating an image sensor according to some example embodiments of the inventive concepts.

Referring to FIG. 17, an image sensor 511 according to some example embodiments may not include the first light blocking pattern 48a and the second light blocking pattern 48b of FIG. 5A. In other words, bottom surfaces of the first low-refractive pattern 50a and the second low-refractive pattern 50b may be in direct contact with the first protective layer 44. Other structures and components may be the same as described with reference to FIG. 5A.

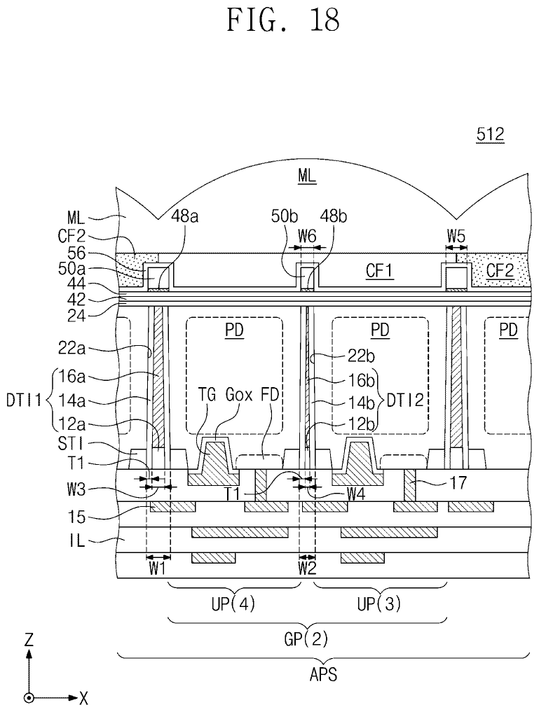

FIG. 18 is a cross-sectional view illustrating an image sensor according to some example embodiments of the inventive concepts.

Referring to FIG. 18, an image sensor 512 according to some example embodiments may not include (e.g., may omit) the connection contact BCA. In FIG. 18, the edge region EG is not illustrated. However, in the edge region EG, a first contact plug 17 may penetrate the first filling insulation pattern 12a so as to be in contact with the first conductive pattern 16a of the first pixel separation portion DTI1. A negative bias voltage may be applied to the first and second conductive patterns 16a and 16b through the first contact plug 17. Other structures and components may be the same as described with reference to FIG. 5A.

In the image sensor according to some example embodiments of the inventive concepts, the second pixel separation portion between the unit pixels constituting each of the pixel groups may include the conductive pattern of which the amount of poly-silicon (capable of absorbing light) is less than that (e.g., the amount of poly-silicon) of the first pixel separation portion between the pixel groups or may exclude the conductive pattern, and thus it is possible to reduce, minimize, or prevent a loss of incident light absorbed in poly-silicon (e.g., in a given pixel group that includes the unit pixels and the second pixel separation portion between at least two unit pixels of the given pixel group). As a result, the amount of received light and photosensitivity of the image sensor may be increased to realize clear image quality, thereby improving the image-generation performance of the image sensor. In addition, the second pixel separation portion provided between the unit pixels may have a relatively narrow width, and thus a total size of the image sensor may be reduced to increase an integration density of the image sensor.

In the image sensor according to some example embodiments of the inventive concepts, the width of the second light blocking pattern disposed on the second pixel separation portion between the unit pixels constituting each of the pixel groups may be less than the width of the first light blocking pattern disposed on the first pixel separation portion between the pixel groups, and thus it is possible to relatively increase the amount of light incident to the unit pixels constituting each of the pixel groups. As a result, the amount of light received in the image sensor may be increased to realize the clear image quality, thereby improving the image-generation performance of the image sensor.

While some example embodiments of the inventive concepts have been particularly shown and described, it will be understood by one of ordinary skill in the art that variations in form and detail may be made therein without departing from the spirit and scope of the attached claims. Features of image sensors according to various example embodiments, including the example embodiments shown in FIGS. 3 to 15, may be combined with each other in one or more image sensors.

What is claimed is:

1. An image sensor comprising:
a substrate comprising a first surface and a second surface opposing the first surface, a pixel array region, and an optical black region adjacent to the pixel array region in a plan view;
an optical black pattern on the optical black region;
a first pixel group in the pixel array region comprising first to fourth pixels arranged in a first 2×2 matrix;
a second pixel group in the pixel array region comprising fifth to eighth pixels arranged in a second 2×2 matrix;
a first micro lens covering the first to fourth pixels;
a second micro lens covering the fifth to eighth pixels;
a first trench in the substrate and encircling the first pixel group and the second pixel group in a plan view; and
a second trench in the substrate and comprising a first portion disposed between the first pixel and the second pixel in the plan view, a second portion disposed between the second pixel and the third pixel, a third portion disposed between the third pixel and the fourth pixel, and a fourth portion disposed between the first pixel and the fourth pixel,
wherein the first to fourth pixels are arranged in a 2×2 matrix form and are sequentially arranged in a clockwise direction,
wherein the first portion is spaced apart from the third portion in a first direction in a plan view,
wherein the second portion is spaced apart from the fourth portion in a second direction perpendicular to the first direction in the plan view,
wherein a width of the first trench between the first pixel group and the second pixel group on the second surface in the first direction is different from a width of the first portion on the second surface in the first direction, and
wherein the image sensor is configured to receive light from the second surface.

2. The image sensor of claim 1, wherein each of the first and second trenches penetrates the substrate.

3. The image sensor of claim 2, further comprising:
a first filling insulation pattern in the first trench and in contact with the second surface; and
a second filling insulation pattern in the second trench and in contact with the second surface.

4. The image sensor of claim 3, wherein the first filling insulation pattern is spaced apart from the first surface, and
wherein the second filling insulation pattern is spaced apart from the first surface.

5. The image sensor of claim 4, further comprising:
a floating diffusion region shared by the first to fourth pixels, and
wherein a width of the floating diffusion region in the first direction in the plan view is greater than the width of the first portion in the first direction in the plan view.

6. The image sensor of claim 4, further comprising:
a floating diffusion region shared by the first to fourth pixels, and
wherein a width of the floating diffusion region in the second direction in the plan view is greater than the width of the fourth portion in the second direction in the plan view.

7. The image sensor of claim 5, further comprising:
a first color filter covering the first to fourth pixels; and
a second color filter covering the fifth to eighth pixels.

8. The image sensor of claim 7, wherein the floating diffusion region is disposed at a center of the first pixel group in the plan view.

9. An image sensor comprising:
a substrate comprising a first surface and a second surface opposing the first surface, a pixel array region, and an optical black region adjacent to the pixel array region in a plan view;
an optical black pattern on the optical black region;
a first pixel group in the pixel array region comprising first to fourth pixels arranged in a first 2×2 matrix;
a second pixel group in the pixel array region comprising fifth to eighth pixels arranged in a second 2×2 matrix;
a first color filter covering the first to fourth pixels;
a second color filter covering the fifth to eighth pixels;
a first trench in the substrate and encircling the first pixel group and the second pixel group in a plan view; and
a second trench in the substrate and comprising a first portion disposed between the first pixel and the second pixel in the plan view, a second portion disposed between the second pixel and the third pixel, a third portion disposed between the third pixel and the fourth pixel, and a fourth portion disposed between the first pixel and the fourth pixel,
wherein the first to fourth pixels are arranged in a 2×2 matrix form and are sequentially arranged in a clockwise direction,
wherein the first portion is spaced apart from the third portion in a first direction in a plan view,
wherein the second portion is spaced apart from the fourth portion in a second direction perpendicular to the first direction in the plan view,
wherein a width of the first trench between the first pixel group and the second pixel group on the second surface in the first direction is different from a width of the first portion on the second surface in the first direction, and
wherein the image sensor is configured to receive light from the second surface.

10. The image sensor of claim 9, further comprising:
a first pattern filling the second trench;
a second pattern disposed between a sidewall of the second trench and the first pattern in a vertical view; and
a third pattern disposed between the first pattern and the first surface,
wherein the first pattern is in contact with the second surface, and
wherein the third pattern is in contact with the first surface.

11. The image sensor of claim 10, wherein the second and third patterns comprise silicon oxide.

12. The image sensor of claim 10, wherein the first pattern comprises a metal layer.

13. The image sensor of claim 11, further comprising:
a floating diffusion region shared by the first to fourth pixels, and
wherein a width of the floating diffusion region in the first direction in the plan view is greater than the width of the first portion in the first direction in the plan view.

14. The image sensor of claim 11, further comprising:
a floating diffusion region shared by the first to fourth pixels, and
wherein a width of the floating diffusion region in the second direction in the plan view is greater than the width of the fourth portion in the second direction in the plan view.

15. The image sensor of claim 13, further comprising:
a first micro lens covering the first to fourth pixels; and
a second micro lens covering the fifth to eighth pixels.

16. The image sensor of claim 13, further comprising:
a fourth pattern filling the first trench;
a fifth pattern disposed between a sidewall of the first trench and the fourth pattern in the vertical view; and
a sixth pattern disposed between the fourth pattern and the first surface,
wherein the fourth pattern is in contact with the second surface, and
wherein the sixth pattern is in contact with the first surface.

17. The image sensor of claim 14, wherein the width of the first trench between the first pixel group and the second pixel group on the second surface in the first direction is different from a width of the first trench on the first surface in the first direction.

18. The image sensor of claim 17, wherein each of the first and second trenches penetrates the substrate.

19. The image sensor of claim 17, wherein the floating diffusion region is disposed at a center of the first pixel group in the plan view.

20. An image sensor comprising:
a substrate comprising a first surface and a second surface opposing the first surface, a pixel array region, and an optical black region adjacent to the pixel array region in a plan view;
an optical black pattern on the optical black region;
a first pixel group in the pixel array region comprising first to fourth pixels arranged in a first 2×2 matrix;
a second pixel group in the pixel array region comprising fifth to eighth pixels arranged in a second 2×2 matrix;
a first micro lens covering the first to fourth pixels;
a second micro lens covering the fifth to eighth pixels;
a first trench in the substrate and encircling the first pixel group and the second pixel group in a plan view; and
a second trench in the substrate and comprising a first portion disposed between the first pixel and the second pixel in the plan view, a second portion disposed between the second pixel and the third pixel, a third portion disposed between the third pixel and the fourth pixel, and a fourth portion disposed between the first pixel and the fourth pixel,
wherein the first to fourth pixels are arranged in a 2×2 matrix form and are sequentially arranged in a clockwise direction,
wherein the first portion is spaced apart from the third portion in a first direction in a plan view,
wherein the second portion is spaced apart from the fourth portion in a second direction perpendicular to the first direction in the plan view,
wherein a width of the first trench between the first pixel group and the second pixel group on the second surface in the first direction is different from a width of the first portion on the second surface in the first direction,
wherein the width of the first trench between the first pixel group and the second pixel group on the second surface in the first direction is different from a width of the first trench on the first surface in the first direction,
wherein each of the first and second trench are filled with a metal layer, and
wherein the image sensor is configured to receive light from the second surface.
